(19) United States
(12) Patent Application Publication
(10) Pub. No.: US 2026/0013251 A1
(43) Pub. Date: Jan. 8, 2026

(54) IMAGE SENSING DEVICE AND METHOD OF MANUFACTURING SAME

(71) Applicant: SK hynix Inc., Icheon-si (KR)

(72) Inventor: Woo Yung JUNG, Icheon-si (KR)

(21) Appl. No.: 18/964,589

(22) Filed: Dec. 1, 2024

(30) Foreign Application Priority Data
Jul. 5, 2024 (KR) 10-2024-0088663

(51) Int. Cl. H10F 39/00

(52) U.S. Cl. CPC H10F 39/8063; H10F 39/024; H10F 39/8053

(57) ABSTRACT

An image sensing device is provided to include a circuit region including a pixel area and a non-pixel area surrounding the pixel area; a photodetector located in the pixel area and configured to receive light and produce an electrical signal in response to the light and disposed in the circuit region; a color filter layer including a portion over the photodetector and configured to allow light having a specific color to pass therethrough; a base disposed over the color filter layer; and a lens layer including a portion over the photodetector to direct incident light to the photodetector and disposed over the base and including a support and a plurality of posts disposed over the support, the plurality of posts being arranged in contact with air.

### CROSS-REFERENCE TO RELATED APPLICATION

This patent document claims the priority and benefits of Korean Patent Application No. 10-2024-0088663, filed Jul. 5, 2024, the entire contents of which is incorporated herein for all purposes by this reference.

### TECHNICAL FIELD

The technology disclosed in this patent document relates to an image sensing device and a method of manufacturing the same.

### BACKGROUND

With the advancement in the information and communication industry and digitalization of electronic devices, image sensors with improved performance are used in various fields such as digital cameras, camcorders, cellular phones, personal communication systems (PCSs), gaming devices, security cameras, medical micro cameras, and the like. Generally, an image sensor has a pixel area including a photodiode and a peripheral circuit region. A unit pixel includes a photodiode and a transfer transistor. The transfer transistor is arranged between the photodiode and the floating diffusion region and transfers charges generated by the photodiode to the floating diffusion region.

### SUMMARY

The disclosed technology can be implemented in some embodiments to provide an image sensing device with improved breakage or peeling phenomenon of the post unit of a meta-lens layer when attaching and detaching a laminating film on the top of the meta-lens layer.

Some implementations of the disclosed technology provide an image sensing device that can reduce the thickness of the post unit of the meta-lens layer.

Some implementations of the disclosed technology provide an image sensing device that can reduce the thickness of the post unit of the meta-lens layer.

Some implementations of the disclosed technology provide an image sensing device that can alleviate the impact applied to the post unit by forming a buffer unit of the meta-lens layer.

Some implementations of the disclosed technology provide a method of manufacturing an image sensing device with improved breakage of the post unit of the meta-lens layer when attaching and detaching a laminating film on the top of the meta-lens layer.

Some implementations of the disclosed technology provide a method of manufacturing an image sensing device that can reduce the thickness of the post unit of the meta-lens layer.

Some implementations of the disclosed technology provide a method of manufacturing an image sensing device that can alleviate the impact applied to the post unit by forming a buffer unit of the meta-lens layer.

The disclosed technology can be also implemented to provide other technical benefits without being limited to those mentioned above. Various technical effects can be inferred from the following embodiments.

In one aspect, an image sensing device is provided to comprise a circuit region including a pixel area and a non-pixel area surrounding the pixel area; a photodetector located in the pixel area and configured to receive light and produce an electrical signal in response to the light and disposed in the circuit region; a color filter layer including a portion over the photodetector and configured to allow light having a specific color to pass therethrough; a base disposed over the color filter layer; and a lens layer including a portion over the photodetector to direct incident light to the photodetector and disposed over the base and including a support and a plurality of posts disposed over the support, the plurality of posts being arranged in contact with air.

In another aspect, an image sensing device is provided to include a circuit region including a pixel area and a non-pixel area surrounding the pixel area; a photodetector disposed in the circuit region; a color filter layer disposed over the photodetector; a base disposed over the color filter layer; and a lens layer disposed over the base and including a plurality of posts disposed over the base and a capping region covering the plurality of posts, wherein air is arranged between two adjacent ones of the plurality of posts.

In another aspect, a method of manufacturing an image sensing device is provided. The method comprises forming a circuit region including a pixel area and a non-pixel area surrounding the pixel area, a photodetector layer in the circuit region, and a color filter layer on the photodetector layer; forming a base over the color filter layer; forming a plurality of posts over the base, the plurality of posts arranged in contact with air; and forming a capping region over the plurality of posts, the capping region forming a lens layer together with the plurality of posts and the base.

Details of other embodiments are included in the detailed description and drawings.

According to the embodiments, as the post unit of the meta-lens layer is formed to be integrated with the support unit, the post unit may be prevented from being broken in the process of attaching and detaching a laminating film on the top of the meta lens layer.

According to the embodiments, as the post unit of the meta-lens layer is arranged within the recess pattern formed in the base unit, the post unit may be prevented from being broken in the process of attaching and detaching a laminating film on the top of the meta lens layer.

According to the embodiments, as the capping unit is formed on the post unit, the post unit may be prevented from being broken in the process of attaching and detaching a laminating film on the top of the meta lens layer.

According to the embodiments, as the meta-lens layer further includes a buffer unit arranged on the non-pixel area, the impact applied to the post unit can be alleviated.

The effects that can be obtained in the present specification are not limited to the effects mentioned above, and those skilled in the art may clearly understand other various effects from the description without being limited thereto.

### BRIEF DESCRIPTION OF THE DRAWINGS

FIG. 1 is a block diagram showing an imaging system based on some embodiments of the disclosed technology.

FIG. 2 is a block diagram showing the image sensing device shown in FIG. 1.

FIG. 3 is a plan view showing the pixel array as shown in FIG. 2.

FIG. 4 is a cross-sectional view taken along line A-A′ of FIG. 3.

FIG. 5 is an enlarged cross-sectional view showing area Q1 of FIG. 4.

FIGS. 6 to 13 are views of each processing step showing a method of manufacturing a pixel array based on some embodiments of the disclosed technology.

FIG. 14 is a cross-sectional view showing a pixel array based on some embodiments of the disclosed technology.

FIGS. 15 to 19 are views of each processing step showing a method of manufacturing a pixel array based on some embodiments of the disclosed technology.

FIG. 20 is a cross-sectional view showing a pixel array based on some embodiments of the disclosed technology.

FIG. 21 is a view of a processing step showing a method of manufacturing a pixel array based on some embodiments of the disclosed technology.

FIG. 22 is a cross-sectional view showing a pixel array based on some embodiments of the disclosed technology.

FIG. 23 is a cross-sectional view showing a pixel array based on some embodiments of the disclosed technology.

FIGS. 24 to 29 are views of each processing step showing a method of manufacturing a pixel array based on some embodiments of the disclosed technology.

FIG. 30 is a cross-sectional view showing a pixel array based on some embodiments of the disclosed technology.

FIG. 31 is a cross-sectional view showing a pixel array based on some embodiments of the disclosed technology.

FIG. 32 is a cross-sectional view showing a pixel array based on some embodiments of the disclosed technology.

FIGS. 33 to 38 are views of each processing step showing a method of manufacturing a pixel array based on some embodiments of the disclosed technology.

FIG. 39 is a cross-sectional view showing a pixel array based on some embodiments of the disclosed technology.

FIG. 40 is a cross-sectional view showing a pixel array based on some embodiments of the disclosed technology.

### DETAILED DESCRIPTION

Hereinafter, example embodiments will be described with reference to the drawings.

Like reference numerals refer to like elements. In addition, in the drawings, the thickness, proportions, and dimensions of components are exaggerated for effective explanation of technical content. “And/or” includes all of one or more combinations that the associated configurations may define.

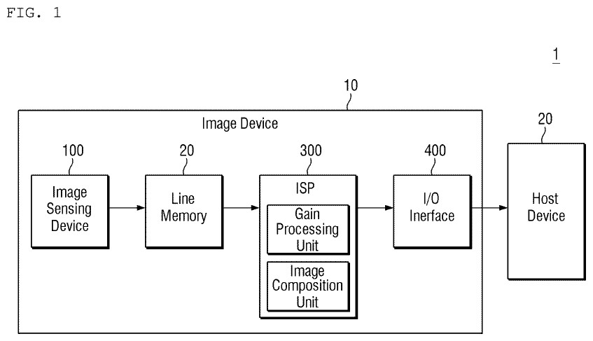

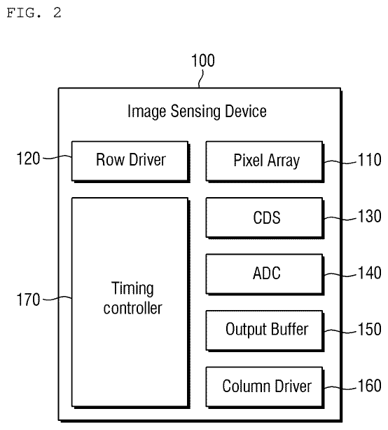

FIG. 1 is a block diagram showing an imaging system based on an embodiment of the disclosed technology. FIG. 2 is a block diagram showing an example of the image sensing device shown in FIG. 1.

Referring to FIG. 1, in some embodiments, an imaging system 1 may refer to a device such as a digital still camera for capturing still images or a digital video camera for capturing or recording videos. For example, the imaging device 10 may be implemented as a digital single lens reflex (DSLR) camera, a mirrorless camera, or a cellular phone (particularly, a smartphone), but it is not limited thereto. The imaging device 10 may include a device including a lens and an image capturing device, which is capable of capturing an object and generating an image.

The imaging system 1 may include an imaging device 10 and a host device 20.

The imaging device 10 may include an image sensing device 100, a line memory 200, an image signal processor (ISP) 300, and an input/output (I/O) interface 400.

The image sensing device 100 may be a Complementary Metal Oxide Semiconductor Image Sensor (CMOS mage sensor or CIS) that converts optical signals into electrical signals. The overall operation of the image sensing device 100, such as on/off operations, operation mode, operation timing, sensitivity, and/or others, may be controlled by the ISP 300. The image sensing device 100 may transmit image data obtained by converting optical signals into electrical signals to the line memory 200 under the control of the ISP 300.

Referring to FIG. 2, the image sensing device 100 may include a pixel array 110, a row driver 120, a Correlate Double Sampler (CDS) 130, an analog-to-digital converter (ADC) 140, an output buffer 150, a column driver 160, and a timing controller 170. Here, each component of the image sensing device 100 is merely an example, and at least some components may be added or omitted as needed.

The pixel array 110 may include a plurality of image pixels arranged in a plurality of rows and a plurality of columns. In an embodiment, the plurality of image pixels may be arranged in a two-dimensional pixel array including rows and columns. In another embodiment, the plurality of image pixels may be arranged in a three-dimensional pixel array. The plurality of image pixels may convert optical signals into electrical signals on a pixel basis or a pixel group basis, and image pixels in a pixel group may share at least a specific internal circuit. The pixel array 110 may receive a pixel control signal including a row selection signal, a pixel reset signal, a transfer signal, or the like from the row driver 120, and a corresponding pixel of the pixel array 110 may be activated by the pixel control signal to perform an operation corresponding to the row selection signal, pixel reset signal, transfer signal, or others. Each of the image pixels may detect incident light by generating photo charges corresponding to the strength (or illuminance) of the incident light and generating an electrical signal of a size corresponding to the quantity of the generated photo charges. For convenience of explanation, the image pixels may also be referred to as pixels.

The row driver 120 may activate the pixel array 110 to perform specific operations on pixels included in a corresponding row on the basis of commands and control signals supplied by the timing controller 170. In an embodiment, the row driver 120 may select at least one pixel arranged in at least one row of the pixel array 110. The row driver 120 may generate a row selection signal to select at least one row among the plurality of rows. The row driver 120 may sequentially enable a pixel reset signal and a transfer signal for pixels corresponding to at least one selected row. Accordingly, a reference signal and an image signal of analog form generated from each of the pixels of the selected row may be sequentially transferred to the correlate double sampler 130. Here, the reference signal may be an electrical signal provided to the correlate double sampler 130 when a sensing node (e.g., floating diffusion region) of the pixel is reset, and the image signal may be an electrical signal provided to the correlate double sampler 130 when photo charges generated by the pixel are accumulated in the sensing node. The reference signal representing pixel-specific reset noise and the image signal representing strength of incident light may be referred to as pixel signals.

The image sensing device 100 may use correlate double sampling to remove unwanted offset values of pixels, such as fixed pattern noise, by sampling the pixel signal twice to remove the difference between two samples. For example, the correlate double sampling removes unwanted offset values by comparing pixel output voltages acquired before and after the photo charges generated by the incident light are accumulated in the sensing node, so that a pixel output voltage based only on the incident light may be measured. In an embodiment, the correlate double sampler 130 may sequentially sample and hold the reference signal and the image signal provided from the pixel array 110 to each of a plurality of column lines. That is, the correlate double sampler 130 may sample and hold the levels of the reference signal and the image signal corresponding to each of the columns of the pixel array 110.

The correlate double sampler 130 may transfer the reference signal and the image signal of each of the columns to the ADC 140 as a correlate double sampling signal on the basis of the control signal received from the timing controller 170.

The ADC 140 may convert the correlate double sampling signal for each column output from the correlate double sampler 130 into a digital signal, and output image data. In an embodiment, the ADC 140 may convert the correlate double sampling signal generated by the correlate double sampler 130 for each of the columns into a digital signal, and output the digital signal.

The ADC 140 may include a plurality of column counters corresponding to each of the columns of the pixel array 110. Each column of the pixel array 110 is connected to each column counter, and image data may be generated by converting a correlate double sampling signal corresponding to each of the columns into a digital signal using the column counters. According to another embodiment, the ADC 140 includes one global counter and may convert a correlate double sampling signal corresponding to each of the columns into a digital signal using a global code provided by the global counter.

The output buffer 150 may temporarily hold and output each image data of column units provided from the ADC 140. The output buffer 150 may temporarily store image data output from the ADC 140 on the basis of the control signal of the timing controller 170. The output buffer 150 may operate as an interface that compensates for the difference in the transmission speed (or processing speed) between different devices connected to the image sensing device 100.

The column driver 160 may select a column of the output buffer 150 on the basis of the control signal of the timing controller 170, and control the output buffer 150 to sequentially output the image data temporarily stored in the selected column. In an embodiment, the column driver 160 may receive an address signal from the timing controller 170, and the column driver 160 may select a column of the output buffer 150 by generating a column selection signal on the basis of the address signal, and control to output the image data from the selected column of the output buffer 150 to the outside.

The timing controller 170 may control at least one among the row driver 120, the correlate double sampler 130, the ADC 140, the output buffer 150, and the column driver 160.

The timing controller 170 may provide a clock signal required for the operation of each component of the image sensing device 100, a control signal for timing control, and an address signal for selecting a row or a column to at least one among the row driver 120, the correlate double sampler 130, the ADC 140, the output buffer 150, and the column driver 160. According to an embodiment, the timing controller 170 may include a logic control circuit, a phase lock loop (PLL) circuit, a timing control circuit, and a communication interface circuit.

Referring to FIG. 1 again, the line memory 200 may include volatile memory (e.g., DRAM, SRAM) and/or non-volatile memory (e.g., flash memory). The line memory 200 may have a capacitance capable of storing image data corresponding to a predetermined number of lines. Here, the line may mean a row of the pixel array 110, and the predetermined number may be a value smaller than the total number of rows of the pixel array 110. Accordingly, the line memory 200 may be a line memory capable of storing image data corresponding to some rows (or lines) of the pixel array 110, not a frame memory capable of storing image data corresponding to frames captured by the pixel array 110 at a time. According to another embodiment, the line memory 200 may be replaced with the frame memory.

The line memory 200 may receive and store image data from the image sensing device 100, and transmit the stored image data to the ISP 300 under the control of the ISP 300.

The ISP 300 may perform image signal processing on the image data stored in the line memory 200. The ISP 300 may reduce noise in the image data, and perform image signal processing for improving image quality, such as gamma correction, color filter array interpolation, color matrix, color correction, color enhancement, lens distortion correction, and the like. In addition, the ISP 300 may generate an image file by compressing the image data generated by performing the image signal processing for improving image quality, or may restore the image data from the image file. The compression format of the image may be a reversible format or a non-reversible format. As an example of the compression format, in the case of still images, the JPEG (Joint Photographic Experts Group) format or JPEG 2000 format may be used. In addition, in the case of a video, a video file may be generated by compressing a plurality of frames according to the Moving Picture Experts Group (MPEG) standard. The image file may be generated according to, for example, the Exchangeable image file format (Exif) standard.

To generate an HDR image, the ISP 300 may include a gain processing unit 310 and an image compositing unit 320.

The gain processing unit 310 may determine a gain operated on the image data (e.g., multiplication operation). The gain processing unit 310 may determine a gain according to the conversion gain difference between the high conversion gain (HCG) mode and the low conversion gain (LCG) mode, and provide the gain to the image compositing unit 320. The gain according to the conversion gain difference may be experimentally determined in advance and stored in the gain processing unit 310. In an embodiment, the gain processing unit 310 may store the experimentally determined gain in a table according to the size of the image data, and the gain processing unit 310 may acquire a gain corresponding to the image data by referring to the table.

Each pixel of the pixel array 110 may operate in any one among the HCG mode and the LCG mode, and the mode of each pixel may be determined by the strength (or illuminance) of light entering each pixel. The HCG mode may mean a mode in which a pixel has a relatively high conversion gain, and the LCG mode may mean a mode in which a pixel has a relatively low conversion gain. Here, the conversion gain may mean a ratio of the level (i.e., voltage) of a pixel signal converted from the photo charges with respect to the quantity of photo charges generated in the pixel. As the quantity of photo charges generated in the pixel is proportional to the illuminance of each pixel, the HCG mode may mean a mode in which the change in the pixel signal according to the change in the illuminance is relatively large, and the LCG mode may mean a mode in which the change in the pixel signal according to the change in the illuminance is relatively small.

Thus, it may be said that the slope of the pixel signal with respect to the illuminance is different in the HCG mode and the LCG mode. The gain may be a correction value for making the slope of the pixel signal (or image data) with respect to the illuminance of a pixel operating in the HCG mode the same as the slope of the pixel signal (or image data) with respect to the illuminance of a pixel operating in the LCG mode.

The image compositing unit 320 may synthesize an HDR image corresponding to a high dynamic range using image data of pixels operating in the HCG mode and/or image data of pixels operating in the LCG mode.

In an embodiment, the image compositing unit 320 may use the gain provided from the gain processing unit 310 in processing the image data of pixels operating in the HCG mode and/or the image data of pixels operating in the LCG mode, and generate an HDR image from the processed image data.

The ISP 300 may transmit, to the input/output interface 400, image data (e.g., HDR image data) obtained after the image signal processing. The image data obtained after the image signal processing may be referred to as the processed image data.

In another embodiment, the gain processing unit 310 and the image compositing unit 320, which are used to generate an HDR image, may be included in the image sensing device 100 instead of the ISP 300.

The input/output interface 400 may perform a communication with the host device 20 and transmit the processed image data to the host device 20. In an embodiment, the input/output interface 400 may be or include a mobile industry processor interface (MIPI). In the implementations, the input/output interface 400 can include various interfaces without being limited to the MIPI.

The host device 20 may be a processor (e.g., an application processor) for processing the image signal-processed image data received from the imaging device 10, a memory (e.g., non-volatile memory) for storing the image data, and a display device (e.g., liquid crystal display (LCD)) for visually outputting the image data.

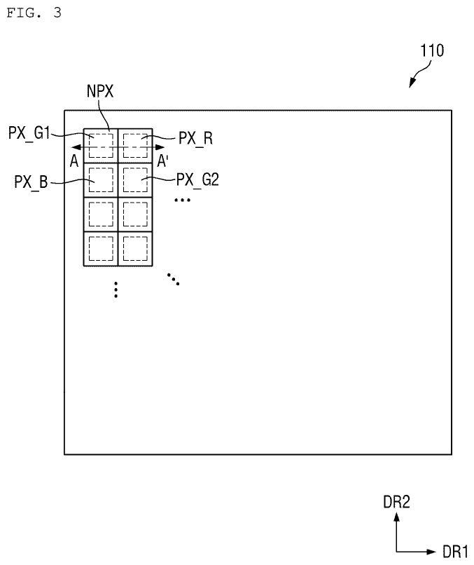

FIG. 3 is a plan view showing an example of a pixel array as shown in FIG. 2.

In the embodiment as shown in FIG. 3, the pixel array 110 may include a plurality of pixels. The plurality of pixels may include a first sub-pixel, a second sub-pixel, a third sub-pixel, and a fourth sub-pixel. Each sub-pixel may include a pixel area and a non-pixel area NPX. For example, each sub-pixel includes a corresponding pixel area, PX_R, PX_G1, PX_G2, or PX_B. The first sub-pixel may be a red pixel that receives red light, the second sub-pixel may be a green pixel that receives green light, the third sub-pixel may be a green pixel that receives green light, and the fourth sub-pixel may be a blue pixel that receives blue light. In the daytime, each pixel may receive light of the visible light wavelength range in correspondence to a wavelength range. In some implementations, the first sub-pixel, the second sub-pixel, the third sub-pixel, and the fourth sub-pixel may further receive light of the infrared wavelength range. In this case, the light reception peak wavelengths of the first sub-pixel may be red wavelength and infrared wavelength, the light reception peak wavelengths of the second sub-pixel and the third sub-pixel may be green wavelength and infrared wavelength, and the light reception peak wavelengths of the fourth sub-pixel may be blue wavelength and infrared wavelength. Since there is almost no light of the visible light wavelength range at night, each pixel may receive light of the infrared wavelength range for each area. In the example, a plurality of pixels may be repeatedly arranged along a first direction DR1 and a second direction DR2. The arrangement of the plurality of pixels may be implemented in various manners without being limited thereto. Color filters may be arranged in the plurality of pixels based on the peak wavelength ranges of the received light. For example, a red color filter may be arranged in the first sub-pixel, a green color filter may be arranged in the second and third sub-pixels, and a blue color filter may be arranged in the fourth sub-pixel.

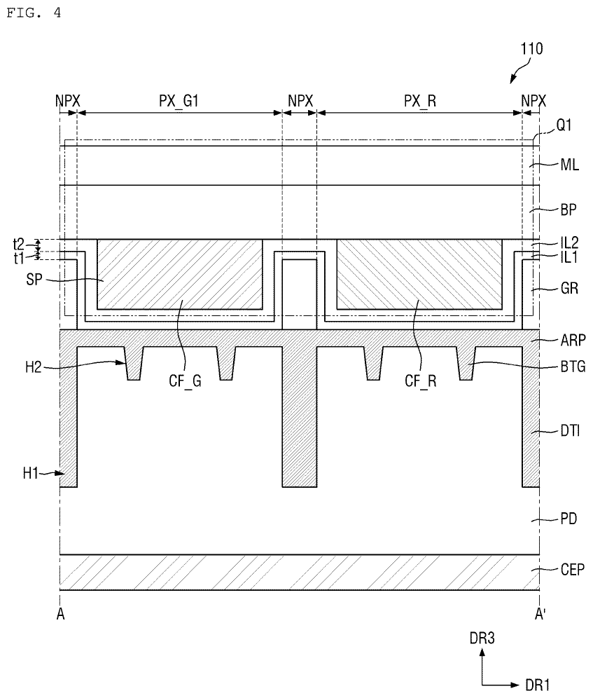

FIG. 4 is a cross-sectional view taken along line A-A′ of FIG. 3. FIG. 4 shows a cross-sectional view of the pixel arrays of the first sub-pixel and the second sub-pixel.

In the example as shown in FIG. 4, the pixel array 110 may include a circuit unit CEP, a photodetector such as a photodiode PD on the circuit unit CEP, a first trench unit DTI and a second trench unit BTG inside the photodiode PD, an anti-reflection layer ARP over or on the photodiode PD, a grid unit GR over or on the non-pixel area NPX, insulating layers IL1 and IL2 on anti-reflection layer ARP, color filters CF_R and CF_G on the insulating layers IL1 and IL2, and a meta-lens layer ML on the color filters CF_R and CF_G. While the photodiode PD is described as the example of the photodetector in the description below, other implementations are also possible as long as it is capable of producing an electrical signal in response to received light. For example, the photodetector can include a photo transistor, a photo gate, or other photosensitive circuitry capable of converting light into a pixel signal (e.g., a charge, a voltage or a current).

The circuit unit CEP is arranged on the bottom surface of the photodiode PD and may include transistors, a wiring layer, and an interlayer insulating layer. The transistors may include an overflow transistor, a transfer transistor, a reset transistor, a driving transistor, and a selection transistor formed on the bottom surface of the photodiode PD.

The photodiode PD may include a single crystal silicon wafer or an epitaxially grown single crystal silicon layer. The photodiode PD may have a high refractive index. For example, although the photodiode PD may have a refractive index of about 2.5 or higher, it is not limited thereto. For example, although the refractive index of the photodiode PD may be about 4 to 6, it is not limited thereto.

In some implementations, the photodiode PD may be formed by injecting P-type and N-type ions. The p-type ions may include boron (B) ions, and the N-type ions may include phosphorous (P) and/or arsenic (As) ions. The photodiode PD functions to receive incident light and convert optical signals into electrical signals. Although the photodiode PD may only refer to the portions corresponding to the pixel areas PX_R and PX_G1, it is not limited thereto.

A first groove H1 and a second groove H2 may be formed in the photodiode PD. Each of the first groove H1 and the second groove H2 may be formed to be indented into the photodiode PD in the thickness direction. For example, the first groove H1 and the second groove H2 extend from a first surface of the photodiode PD toward a second, opposite surface of the photodiode PD. The depth of the first groove H1 may be greater than the depth of the second groove H2. The first groove H1 may be formed in the non-pixel area NPX, and the second groove H2 may be formed in the pixel areas PX_R and PX_G1. The first trench unit DTI may be arranged in the first groove H1, and the second trench unit BTG may be formed in the second groove H2. The number of second grooves H2 provided in one pixel area PX_R or PX_G1 can be varied. For example, one, two, three or more than three second grooves H2 may be provided in one pixel area PX_R or PX_G1. Accordingly, the number of the second trench units BTG provided in one pixel area PX_R or PX_G1 can be varied as well. For example, one, two, three, or more than three second trench units BTG may be provided in one pixel area PX_R or PX_G1. The first trench unit DTI and the second trench unit BTG may include the same material. For example, the first trench unit DTI and the second trench unit BTG may include an insulating material. For example, although examples of the insulating material include hafnium oxide HfO₂, silicon oxide SiO₂, and the like, it is not limited thereto. Although the refractive index of the first trench unit DTI and the second trench unit BTG may be, for example, about 1.4 to about 2.0, it is not limited thereto. The first trench unit DTI may perform a function of totally reflecting the light entering the first trench unit DTI toward the photodiode PD, and the second trench unit BTG may perform a function of scattering the light entering from a light collection pattern MLP. The first trench unit DTI and the second trench unit BTG may perform a function of increasing the path of light by total reflecting the light toward the photodiode PD or scattering the light, respectively. Thus, the trench units may perform a function of increasing the photoelectric conversion efficiency of the photodiode PD.

The anti-reflection layer ARP may be arranged on the photodiode PD and the trench units DTI and BTG. The anti-reflection layer ARP may directly contact the trench units DTI and BTG and the photodiode PD. The anti-reflection layer ARP may include the same material as the trench units DTI and BTG. The anti-reflection layer ARP may be formed in the same process as the trench units DTI and BTG and integrally connected to the trench units DTI and BTG. The anti-reflection layer ARP may perform a function of preventing light entering from the meta-lens layer ML from being totally reflected by the photodiode PD. To this end, the anti-reflection layer ARP may have a refractive index between the refractive index of the color filters CF_R and CF_G and the refractive index of the photodiode PD, but it is not limited thereto. For example, although the refractive index of the anti-reflection layer ARP may be about 1.4 to 2.0, it is not limited thereto. The anti-reflection layer ARP may be arranged across the pixel areas PX_R and PX_G1 and the non-pixel area NPX.

A grid unit GR may be arranged on the anti-reflection layer ARP. The grid unit GR may be arranged over or on the non-pixel area NPX. The grid unit GR may include a low refractive layer that allows light to pass through whit minimal refraction. For example, the grid unit GR may include a low refractive insulating material or an air structure (e.g., a structure including air). In an embodiment, the grid unit GR may include an air structure. The grid unit GR may be arranged in the non-pixel area NPX and perform a function of totally reflecting light entering the grid unit GR. The grid unit GR may prevent light color mixture between adjacent pixel areas PX_R and PX_G1. In some embodiments, the grid unit GR may include metal. For example, although the grid unit GR may include tungsten W, it is not limited thereto.

The insulating layers IL1 and IL2 may be arranged on the grid unit GR. The insulating layers IL1 and IL2 may include a first insulating layer IL1 and a second insulating layer IL2 on the first insulating layer IL1. While the example as shown in FIG. 4 shows two insulating layers IL1 and IL2, other implementations are also possible. For example, the insulating layer may include a single layer or three or more layers. The first insulating layer IL1 may include an insulating material. For example, although the first insulating layer IL1 may include silicon oxide SiO₂, it is not limited thereto. The second insulating layer IL2 may include an insulating material. For example, the second insulating layer IL2 may include silicon oxide SiO₂. The first insulating layer IL1 and the second insulating layer IL2 include various insulating materials without being limited to silicon oxide SiO₂. The thickness t1 of the first insulating layer IL1 may be smaller than the thickness t2 of the second insulating layer IL2, and the free volume value of the first insulating layer IL1 may be larger than the free volume value of the second insulating layer IL2. The first insulating layer IL1 may be formed on an area where the grid unit GR will be formed in the process of forming the grid unit GR having an air structure. Oxygen is radiated on the first insulating layer IL1, and the radiated oxygen passes through the first insulating layer IL1 and oxidizes the carbon layer filling the area where the grid unit GR will be formed. The oxidized carbon layer turns into carbon dioxide and is removed to form a grid unit GR having an air structure. Therefore, the first insulating layer IL1 may include a porous layer. To have a porous layer, the first insulating layer IL1 may have the free volume value larger than that of the second insulating layer IL2. In addition, in order to transmit the oxygen, it is desirable that the thickness of the first insulating layer IL1 is smaller than that of the second insulating layer IL2.

The color filters CF_R and CF_G may be arranged on the second insulating layer IL2. The first color filter CF_R may receive light of the red wavelength range and block light of other wavelength ranges, and the second color filter CF_G may receive light of the green wavelength range and block light of other wavelength ranges. Although the surfaces of the color filters CF_R and CF_G may be positioned on the same line as the surface of the second insulating layer IL2, it is not limited thereto.

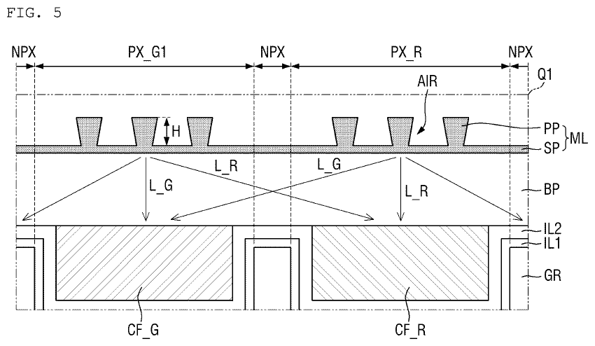

Referring to FIG. 5, a base unit BP may be arranged on the color filters CF_R and CF_G and the second insulating layer IL2. The base unit BP may be arranged between the meta-lens layer ML and the color filters CF_R and CF_G. The base unit BP may include a low temperature oxide (LTO) film. The low temperature oxide (LTO) film may be formed at a low temperature lower than 200° C. For example, the low temperature oxide film may include silicon oxide SiO₂. The low temperature oxide film may include other various materials, such as silicon oxide nitride SiON or hafnium oxide HfO₂. The silicon oxide SiO₂, silicon oxide nitride SiON, and hafnium oxide HfO₂ are examples only and other various materials can be included in the low temperature oxide film.

The meta-lens layer ML may be arranged on the base unit BP. The meta-lens layer ML may perform a function of receiving light entering from the outside into the pixel areas PX_R and PX_G1. Details of the meta-lens layer ML will be further described with reference to FIG. 5. While the meta-lens layer ML is described in the example, various implementations of the disclosed technology include various lens layers without being limited to the meta-lens layer as long as the lens layer functions to receive light and direct the received light to corresponding pixel areas.

FIG. 5 is an enlarged cross-sectional view showing area Q1 of FIG. 4.

Referring to FIGS. 4 and 5, the meta-lens layer ML may include a support unit SP and a post unit PP on the support unit SP. The support unit SP and the post unit PP may be formed in one piece and include the same material. The support unit SP may be arranged on the base unit BP. The support unit SP may be arranged across the pixel areas PX_G1 and PX_R and the non-pixel area NPX. The support unit SP may include, for example, oxide. For example, the support unit SP may include titanium oxide TiO₂, without being limited thereto. The post unit PP may be provided in plural. The plurality of post units PP may be arranged in each pixel area, PX_G1 and PX_R. In the embodiment as shown in FIG. 5, the cross-sectional shape of the post unit PP may be, for example, a trapezoid of an inverted taper shape, but other implementations are also possible. Adjacent post units PP may be spaced apart from each other. For example, each post unit PP may be in contact with air AIR. Thus, air may be arranged between the adjacent post units PP.

As the plurality of post units PP is formed to be integrated with the support unit SP, they may not be broken although air AIR is arranged between the adjacent post units PP.

As shown in FIG. 5, the meta-lens layer ML may perform a function of receiving white light including first light L_R and second light L_G and directing the first light L_R to enter the pixel area PX_R and the second light L_G to enter the second pixel area PX_G1. For example, when the white light enters the first pixel area PX_R, the meta-lens layer ML allows the first light L_R of the white light entering the first pixel area PX_R to be provided to the first color filter CF_R and allows the second light L_G of the white light entering the first pixel area PX_R to be provided to the second color filter CF_G. In addition, when the white light enters the second pixel area PX_G1, the meta-lens layer ML allows the first light L_R of the white light entering the second pixel area PX_G1 to be provided to the first color filter CF_R and the second light L_G of the white light entering the second pixel area PX_G1 to be provided to the second color filter CF_G. The post unit PP and the air AIR of the meta-lens layer ML may have different refractive indices. For example, although the refractive index of the air AIR may be 1.0, and the refractive index of the post unit PP may be about 1.8 to 2.3, the embodiments of the present specification are not limited thereto. Due to the difference in the refractive index between the post unit PP and the air AIR, a phase difference occurs between the light going out from the post unit PP and the light going out from the air AIR, and therefore, the white light entering the meta-lens layer ML may be separated by the wavelength range and selectively enter the color filters CF_G and CF_R of the pixel areas PX_G1 and PX_R, respectively. In order for the meta-lens layer ML to separate the white light by the wavelength range to be optically effective and selectively input the separated light into the color filters CF_G and CF_R of the pixel areas PX_G1 and PX_R, respectively, it is desirable that the thickness of the post unit PP is large. In an embodiment, by arranging air AIR between adjacent post units PP, which has a large difference in the refractive index from that of the post unit PP, there is an advantage in that the thickness of the post unit PP can be reduced. For example, although the thickness H of the post unit PP may be about 600 to 700 nm, the embodiments of the present specification are not limited thereto.

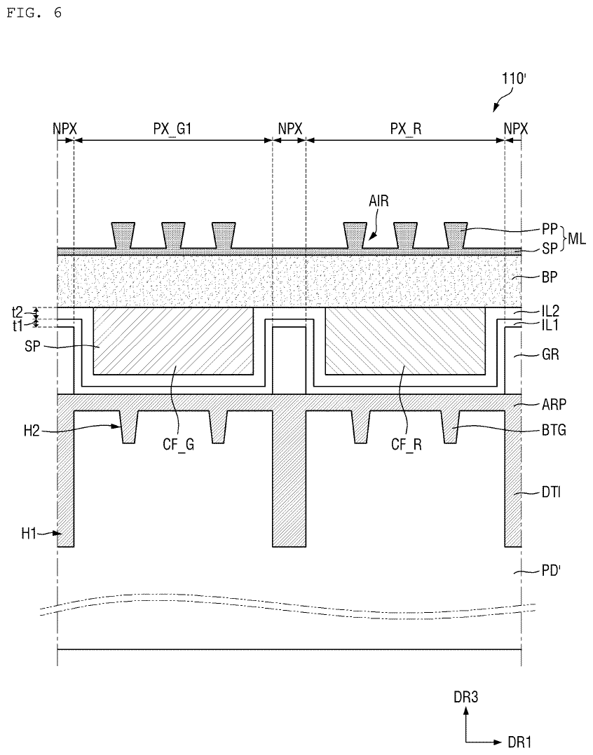

FIGS. 6 to 13 are views of each processing step showing a method of manufacturing a pixel array based on an embodiment of the disclosed technology.

In the example as shown in FIG. 6, a pixel array 110′ may include a photodiode layer PD′ that is before performing grinding. The grinding process is performed to shape and polish the surface of the photodiode layer PD′. The pixel array 110′ may include a photodiode layer PD′, a first trench unit DTI and a second trench unit BTG that are provided inside the photodiode layer PD′, an anti-reflection layer ARP on the photodiode layer PD′, a grid unit GR over or on the non-pixel area NPX, insulating layers IL1 and IL2 on the anti-reflection layer ARP, color filters CF_R and CF_G on the insulating layers IL1 and IL2, and a meta-lens layer ML on the color filters CF_R and CF_G. The photodiode layer PD′, the first trench unit DTI and the second trench unit BTG that are inside the photodiode layer PD′, the anti-reflection layer ARP on the photodiode layer PD′, the grid unit GR over or on the non-pixel area NPX, the insulating layers IL1 and IL2 on the anti-reflection layer ARP, the color filters CF_R and CF_G on the insulating layers IL1 and IL2, and the meta-lens layer ML on the color filters CF_R and CF_G have been already described above with reference to FIGS. 4 and 5, and thus detailed description thereof will be omitted.

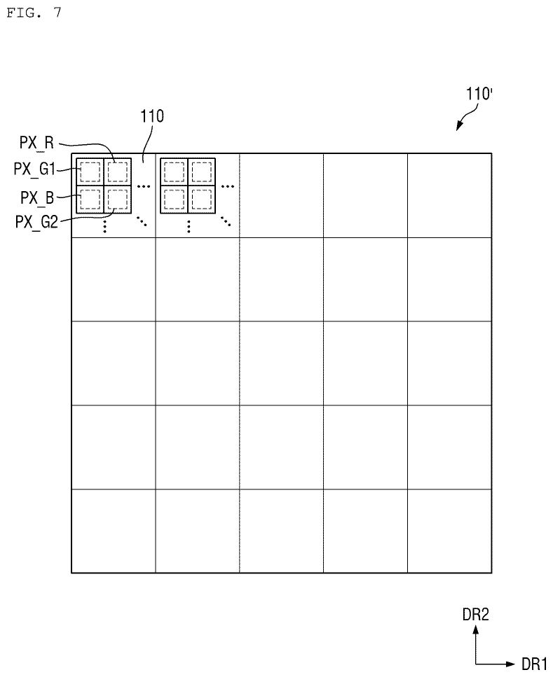

As shown in FIG. 7, the pixel array 110′ may include a plurality of the pixel arrays 110 described in FIG. 3.

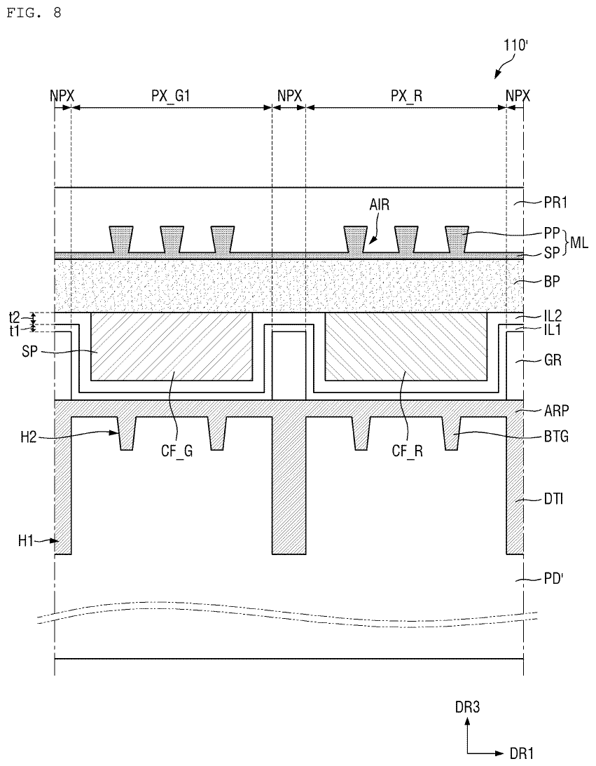

As shown in FIG. 8, a first photoresist PR1 is applied on the meta-lens layer ML. The first photoresist PR1 may include an organic insulating material. The first photoresist PR1 may be arranged between adjacent post units PP and on top of the post units PP.

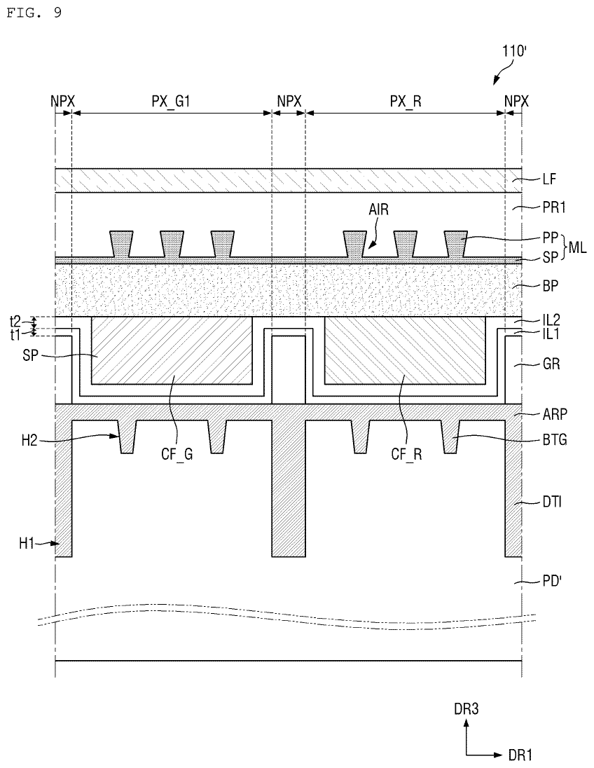

As shown in FIG. 9, an insulating film LF is arranged on the first photoresist PR1.

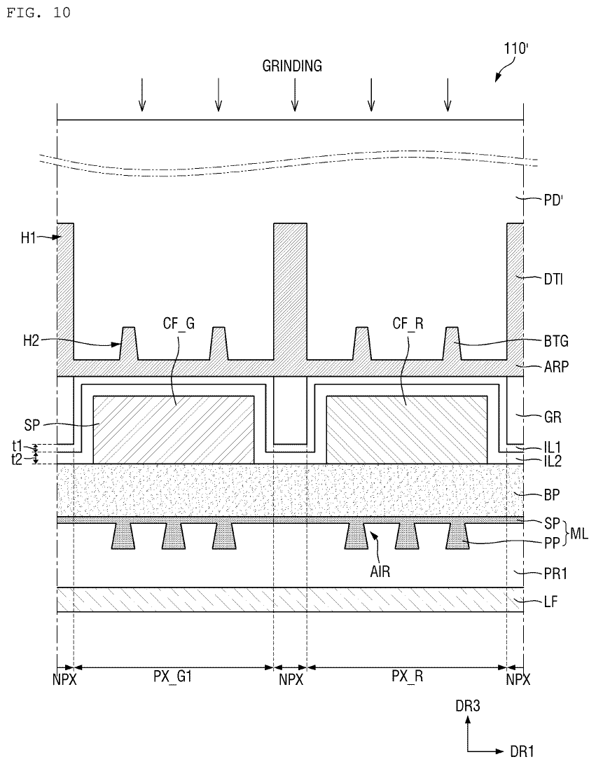

Subsequently, as shown in FIG. 10, the insulating film LF is arranged at the bottom, and the photodiode layer PD′ located at the top is ground.

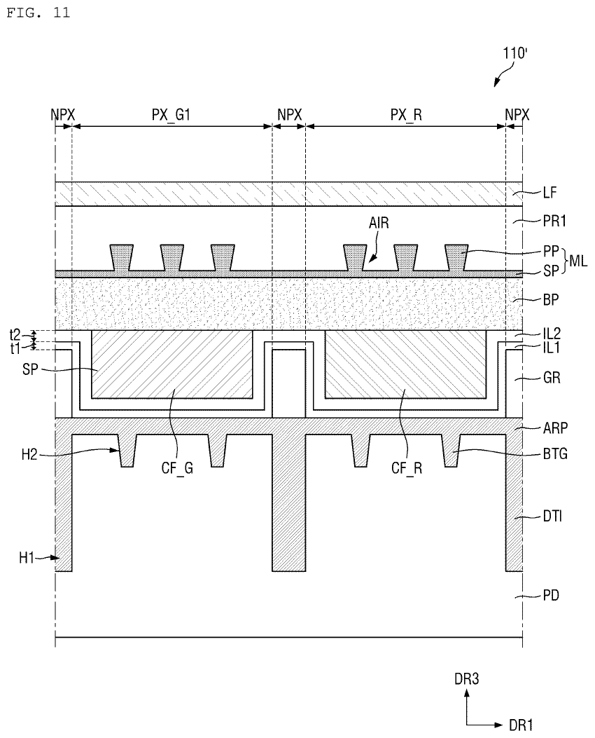

Subsequently, as shown in FIG. 11, a photodiode PD is formed through grinding of the photodiode layer (see PD′ in FIG. 10). After the grinding, the insulating film LF is arranged again on the top.

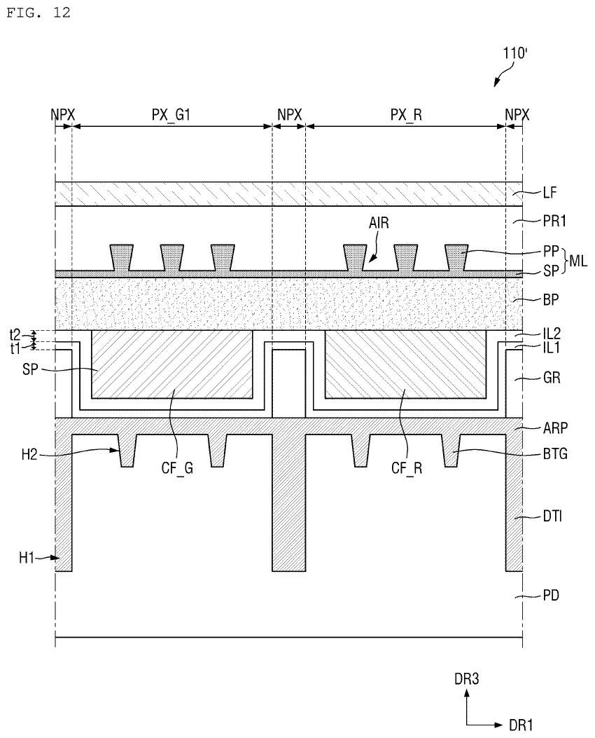

Subsequently, as shown in FIG. 12, the insulating film LF is peeled off. In the conventional process of peeling off the insulating film LF, the plurality of post units PP may be broken as physical impact is applied. However, according to the image sensing device (see 100 in FIG. 1) according to an embodiment, as a plurality of post units PP is formed to be integrated with the support unit SP on the bottom, and the first photoresist PR1 covers and protects the post units PP, the physical impact applied to the plurality of post units PP is alleviated and thus the plurality of post units PP may be prevented from being broken.

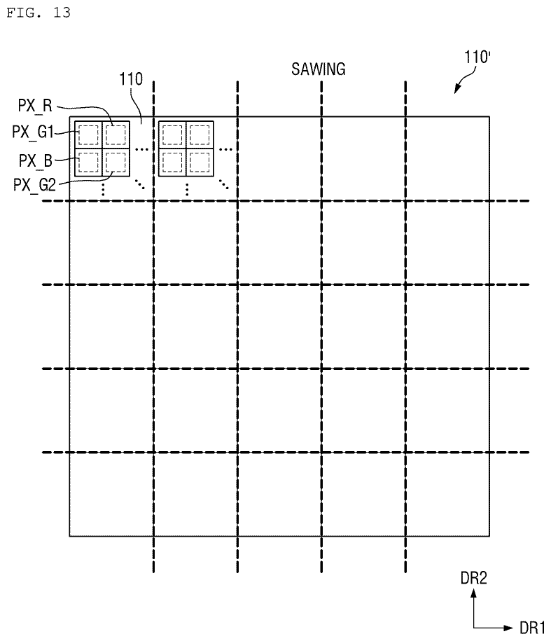

Subsequently, as shown in FIG. 13, the sawing process is proofed to cut each pixel array 110 from the pixel array 110′ in units of cells. The pixel array 110 cut from the pixel array 110′ is the same as the pixel array 110 of FIG. 3.

Hereinafter, a pixel array according to another embodiment will be described. While describing the embodiments below, redundant description of the elements having the same reference numerals and configurations as those described in FIGS. 1 to 13 will be omitted.

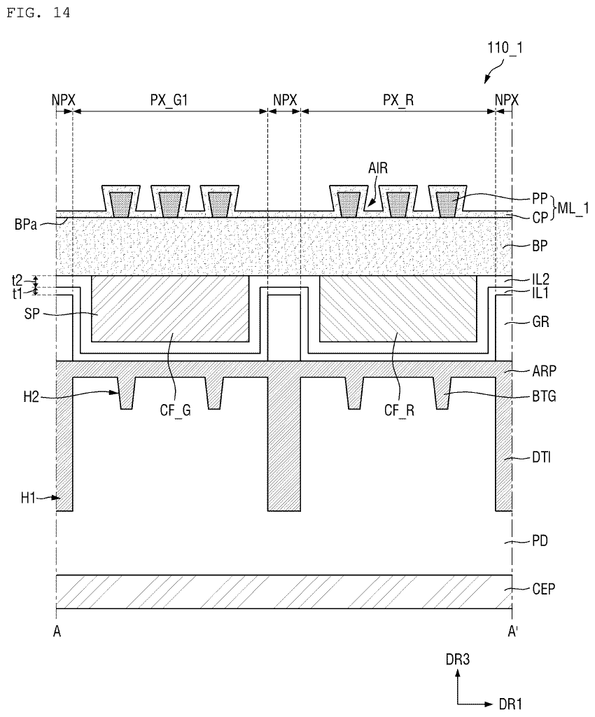

FIG. 14 is a cross-sectional view showing a pixel array based on another embodiment of the disclosed technology.

In the embodiment as shown in FIG. 14, a meta-lens layer ML_1 of the pixel array 110_1 is different from the meta lens layer ML according to FIG. 5 in that the support unit SP is omitted, and a capping unit CP is further included.

In this implementation, a plurality of post units PP may be directly arranged on the base unit BP. The capping unit CP may be arranged on the top surface BPa of the base unit BP and the side and top surfaces of the post units PP. The capping unit CP may include the same material as the base unit BP. For example, the capping unit CP may include a low temperature oxide (LTO) film. The low temperature oxide (LTO) film may be formed at a low temperature lower than 200° C. For example, although the low temperature oxide film may include silicon oxide SiO₂, the embodiments of the present specification are not limited thereto. For example, although the capping unit CP may include silicon oxide nitride SiON or hafnium oxide HfO₂, the embodiments of the present specification are not limited thereto.

In this embodiment, the pixel array 110_1 includes the capping unit CP that is directly arranged on the top surface BPa of the base unit BP and the side and top surfaces of the post units PP. With the capping unit CP provided in the pixel array 110_1, the physical impact applied to the plurality of post units PP is alleviated and thus the plurality of post units PP can be prevented from being broken.

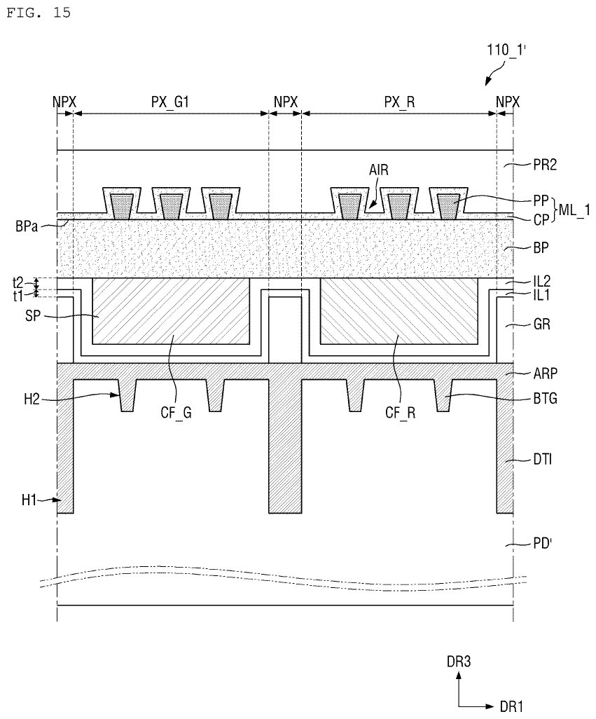

FIGS. 15 to 19 are views of each processing step showing a method of manufacturing a pixel array based on another embodiment of the disclosed technology.

As shown in FIG. 15, the second photoresist PR2 is formed on the base unit BP of the pixel array 110_1′. The second photoresist PR2 may have a predetermined thickness t5. The second photoresist PR2 may be formed in an area excluding the area where the post units PP of FIG. 14 are arranged.

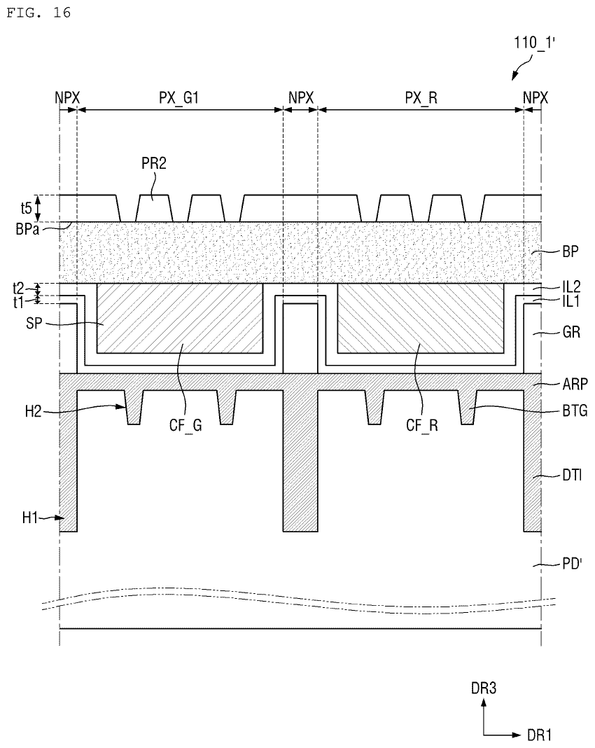

Subsequently, as shown in FIG. 16, a post layer PP′ is formed on the second photoresist PR2. The post layer PP′ may include, for example, oxide. For example, although the post layer PP′ may include titanium oxide TiO₂, the embodiments of the present specification are not limited thereto.

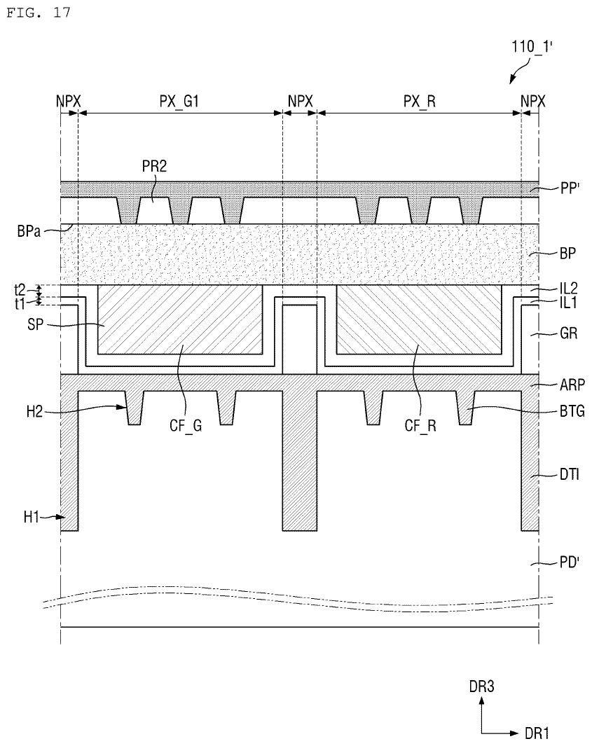

Subsequently, as shown in FIG. 17, the post unit PP is formed by removing the post layer PP′ on the second photoresist PR2. Although the process of removing the post layer PP′ on the second photoresist PR2 may be chemical mechanical polishing (CMP), the embodiments of the present specification are not limited thereto. By removing the post layer PP′ on the second photoresist PR2, the top surface of the second photoresist PR2 and the top surface of the post unit PP may be positioned on the same line.

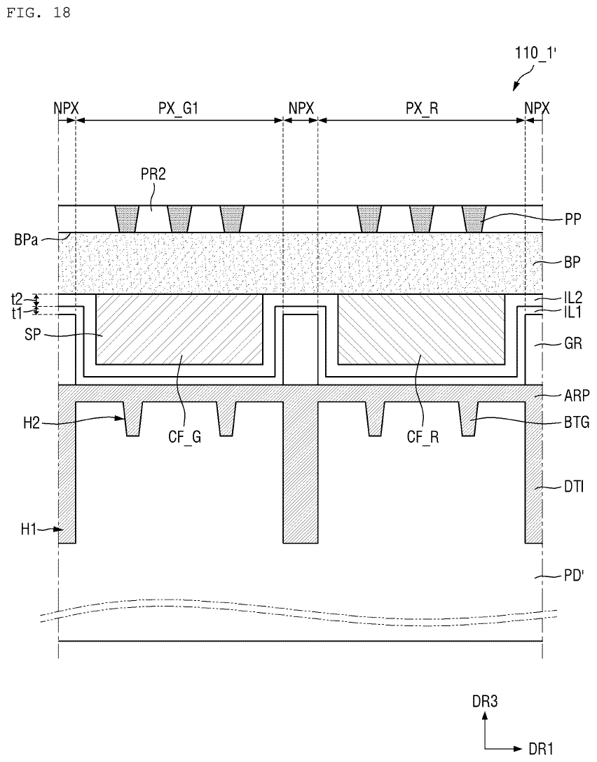

Subsequently, as shown in FIG. 18, the second photoresist PR2 is removed.

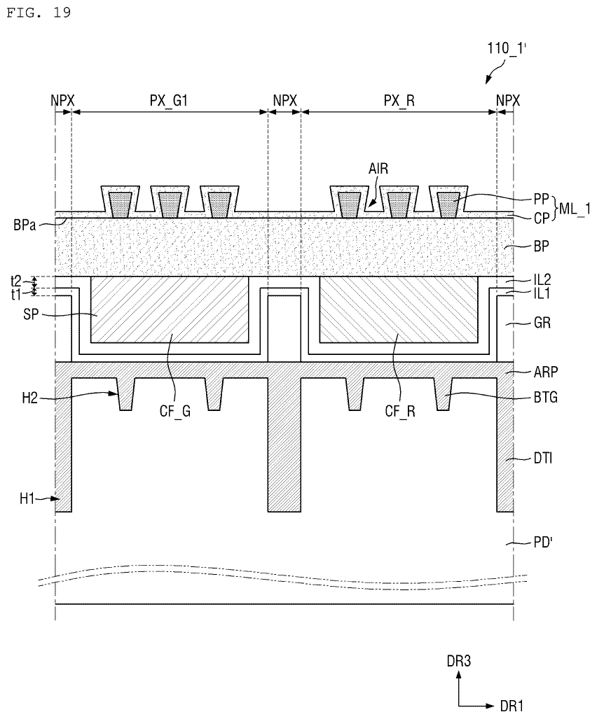

Subsequently, as shown in FIG. 19, a capping unit CP is formed. The capping unit CP may be arranged on the top surface BPa of the base unit BP and the side and top surfaces of the post units PP, respectively. The capping unit CP may include the same material as the base unit BP. For example, the capping unit CP may include a low temperature oxide (LTO) film. The low temperature oxide (LTO) film may be formed at a low temperature lower than 200° C. For example, although the low temperature oxide film may include silicon oxide SiO₂, the embodiments of the present specification are not limited thereto. For example, although the capping unit CP may include silicon oxide nitride SiON or hafnium oxide HfO₂, the embodiments of the present specification are not limited thereto.

Subsequently, application of the first photoresist PR1 described in FIG. 8, arrangement of the insulating film LF described in FIG. 9, grinding of the photodiode layer PD′ described in FIG. 10, peeling of the insulating film LF described in FIG. 12, and sawing in units of cells described in FIG. 13 are proceeded sequentially.

As described above, in the process of peeling off the insulating film LF, the plurality of post units PP may be broken as physical impact is applied. However, according to the pixel array (110_1 in FIG. 14) according to this embodiment, as the capping unit CP is directly arranged on the top surface BPa of the base unit BP and the side and top surfaces of the post units PP, the plurality of post units PP may be prevented from being broken as the physical impact applied to the plurality of post units PP is alleviated, and as the first photoresist PR1 covers and protects the post units PP, the plurality of post units PP may be prevented from being broken as the physical impact applied to the plurality of post units PP is alleviated.

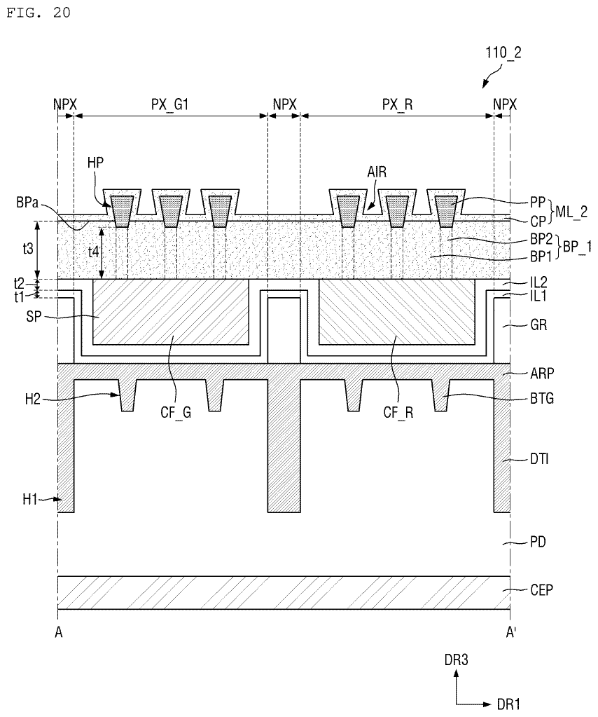

FIG. 20 is a cross-sectional view showing a pixel array according to another embodiment.

Referring to FIG. 20, a pixel array 110_2 according to another embodiment is different from the pixel array 110_1 according to FIG. 14 in that the base unit BP_1 includes a recess pattern HP, and the post unit PP of the meta-lens layer ML_2 is arranged on the recess pattern H.

Describing in more detail, the base unit BP_1 may include a recess pattern HP. The top surface BPa of the base unit BP_1 on which the recess pattern HP is formed may be recessed downward compared to the top surface BPa of the base unit BP_1 where the recess pattern HP is not formed. For example, the base unit BP_1 may include a first base unit BP1 in which the recess pattern HP is not formed, and a second base unit BP2 in which the recess pattern HP is formed. The thickness t4 of the second base unit BP2 may be smaller than the thickness t3 of the first base unit BP1.

The post unit PP may be arranged on the recess pattern HP. The post unit PP may be directly arranged on the top surface BPa of the second base unit BP2. Accordingly, the side surface of the post unit PP may directly contact the first base unit BP1.

As described above, in the process of peeling off the insulating film (see LF in FIG. 12), the plurality of post units PP may be broken as physical impact is applied. However, according to the pixel array 110_2 in this embodiment, as the capping unit CP is directly arranged on the top surface BPa of the base unit BP and the side and top surfaces of the post units PP, and the post unit PP is arranged and fixed on the recess pattern HP, the plurality of post units PP may be prevented from being broken. In addition, as shown in FIG. 8, as the first photoresist PR1 covers and protects the post units PP, the plurality of post units PP may be prevented from being broken as the physical impact applied to the plurality of post units PP is alleviated.

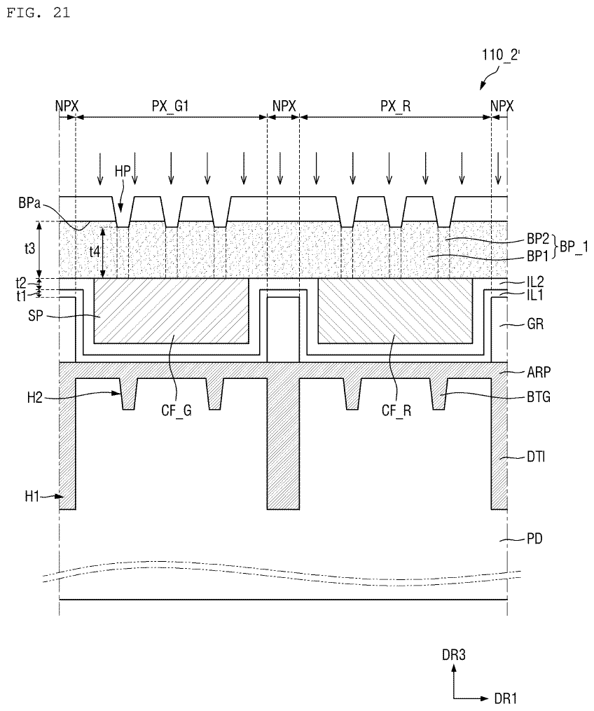

FIG. 21 is a view of a processing step showing a method of manufacturing a pixel array based on another embodiment of the disclosed technology.

Referring to FIGS. 20 and 21, in the pixel array 110_2′ according to this embodiment, an etching process (or a recess process) of the base unit BP_1 may be added between the formation of the second photoresist PR2 illustrated in FIG. 15 and the formation of the post layer PP′ illustrated in FIG. 16. The base unit BP_1 described above in FIG. 20 may be formed through the etching process (or recess process) of the base unit BP_1.

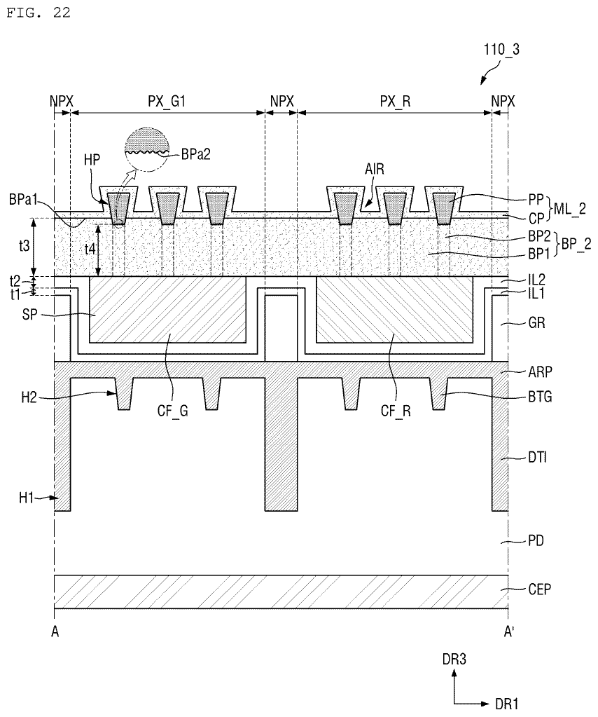

FIG. 22 is a cross-sectional view showing a pixel array based on another embodiment of the disclosed technology.

Referring to FIG. 22, the pixel array 110_3 according to this embodiment is different from the pixel array 110_2 according to FIG. 20 in that the top surface BPa2 of the second base unit BP2 of the base unit BP_2 may have surface irregularities.

In this implementation, the top surface BPa2 of the second base unit BP2 may have surface irregularities.

The surface irregularities of the top surface BPa2 of the second base unit BP2 may be formed in the etching process (or recess process) of the base unit BP_1 described above in FIG. 21. The roughness of the top surface BPa2 of the second base unit BP2 may be greater than the roughness of the top surface BPa1 of the first base unit BP1.

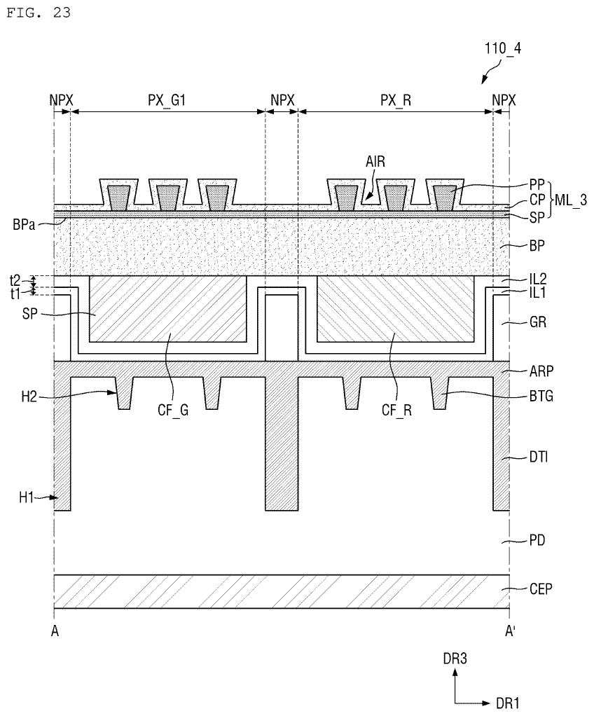

FIG. 23 is a cross-sectional view showing a pixel array based on another embodiment of the disclosed technology.

Referring to FIG. 23, the meta-lens layer ML_3 of the pixel array 110_4 according to this embodiment is different from the pixel array 110_1 according to FIG. 14 in that it further includes a support unit SP on the base unit BP.

In this implementation, the support unit SP may be arranged between the post units PP and the base unit BP, and the capping unit CP may directly contact the top surface of the support unit SP between adjacent post units PP.

The support unit SP may include the same material as the post units PP. The support unit SP may be arranged across the pixel areas PX_G1 and PX_R and the non-pixel area NPX. The support unit SP may include, for example, oxide. For example, although the support unit SP may include titanium oxide TiO₂, the embodiments of the present specification are not limited thereto.

As the plurality of post units PP is directly arranged on the support unit SP, they may not be broken although air AIR is arranged between adjacent post units PP.

In addition, as the capping unit CP is directly arranged on the top surface of the support unit SP and the side and top surfaces of the post units PP, the plurality of post units PP may be prevented from being broken as the physical impact applied to the plurality of post units PP is alleviated. In addition, as shown in FIG. 8, as the first photoresist PR1 covers and protects the post units PP, the plurality of post units PP may be prevented from being broken as the physical impact applied to the plurality of post units PP is alleviated.

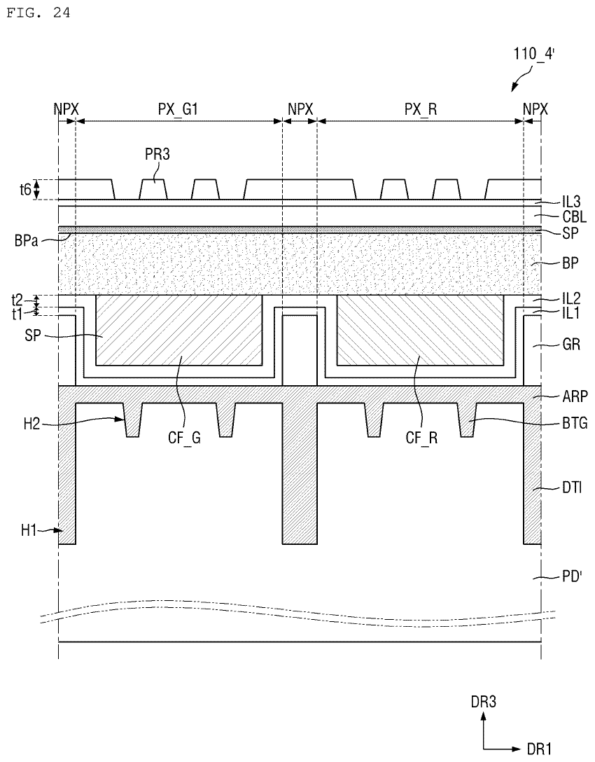

FIGS. 24 to 29 are views of each processing step showing a method of manufacturing a pixel array according to another embodiment.

As shown in FIGS. 23 and 24, a support unit SP, a carbon layer CBL, and a third insulating layer IL3 are sequentially stacked on the base unit BP of the pixel array 110_3′, and a third photoresist PR3 is formed on the third insulating layer IL3. The thickness t6 of the third photoresist PR3 may be smaller than the thickness t5 of the second photoresist PR2 in FIG. 15. The support unit SP may include, for example, oxide. For example, although the support unit SP may include titanium oxide TiO₂, the embodiments of the present specification are not limited thereto. Although the carbon layer CBL may include a carbon material, the embodiments of the present specification are not limited thereto. Although the third insulating layer IL3 may include silicon oxide nitride SiON or hafnium oxide HfO₂, the embodiments of the present specification are not limited thereto.

According to the method of manufacturing a pixel array 110_3′ suggested in this embodiment, the process may be facilitated by reducing the thickness t6 of the third photoresist PR3 compared to the thickness t5 of the second photoresist PR2 in FIG. 15. For example, when the thickness of the photoresist is large, it may be difficult to form fine holes in the photoresist. However, according to the method of manufacturing a pixel array 110_3′ according to this embodiment, fine holes can be easily formed in the third photoresist PR3 by reducing the thickness t6 of the third photoresist PR3.

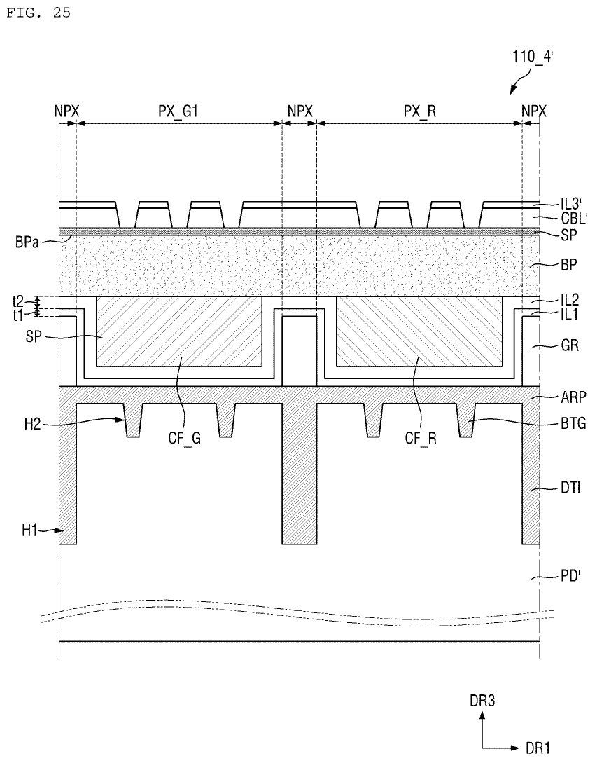

Subsequently, as shown in FIG. 25, a carbon layer CBL′ and a third insulating layer IL3′ are formed using the third photoresist PR3 as a mask. Each of the carbon layer CBL′ and the third insulating layer IL3′ may be configured of a plurality of patterns.

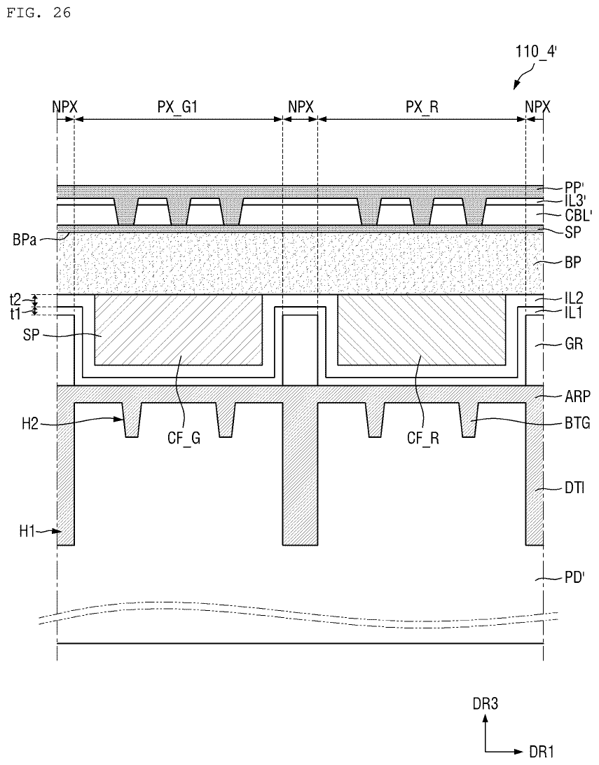

Subsequently, as shown in FIG. 26, a post layer PP′ is formed on the carbon layer CBL′ and the third insulating layer IL3′. The post layer PP′ may include, for example, oxide. For example, although the post layer PP′ may include titanium oxide TiO₂, the embodiments of the present specification are not limited thereto.

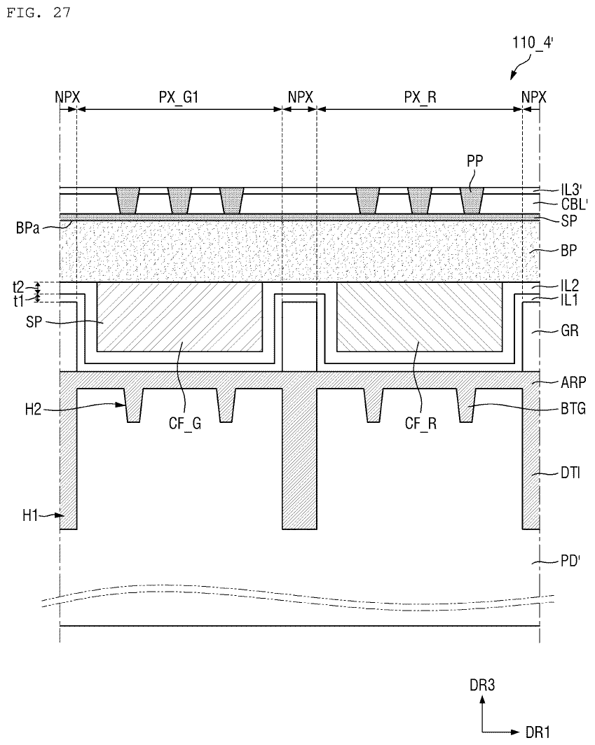

Subsequently, as shown in FIG. 27, the post unit PP is formed by removing the post layer PP′ on the third photoresist PR3. Although the process of removing the post layer PP′ on the third photoresist PR3 may be chemical mechanical polishing (CMP), the embodiments of the present specification are not limited thereto. By removing the post layer PP′ on the third photoresist PR3, the top surface of the third insulating layer IL3′ and the top surface of the post unit PP may be positioned on the same line.

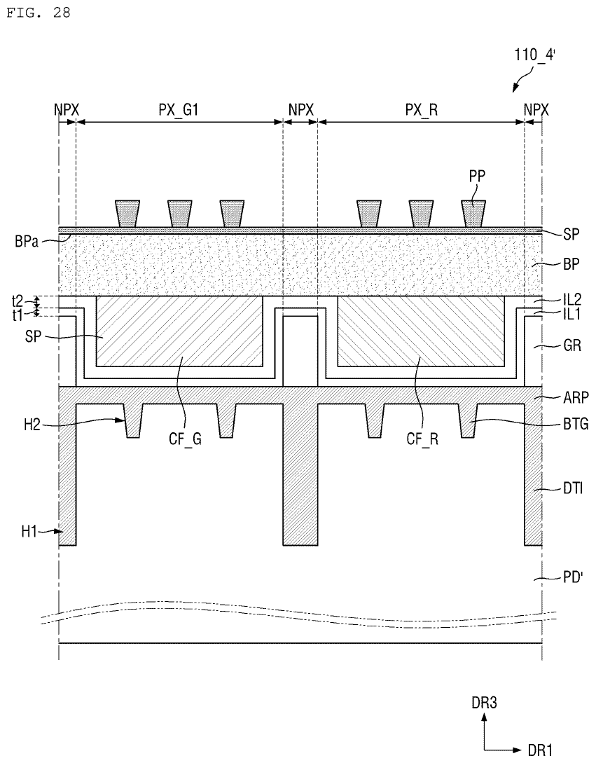

Subsequently, as shown in FIG. 28, the carbon layer CBL′ and third insulating layer IL3′ are removed.

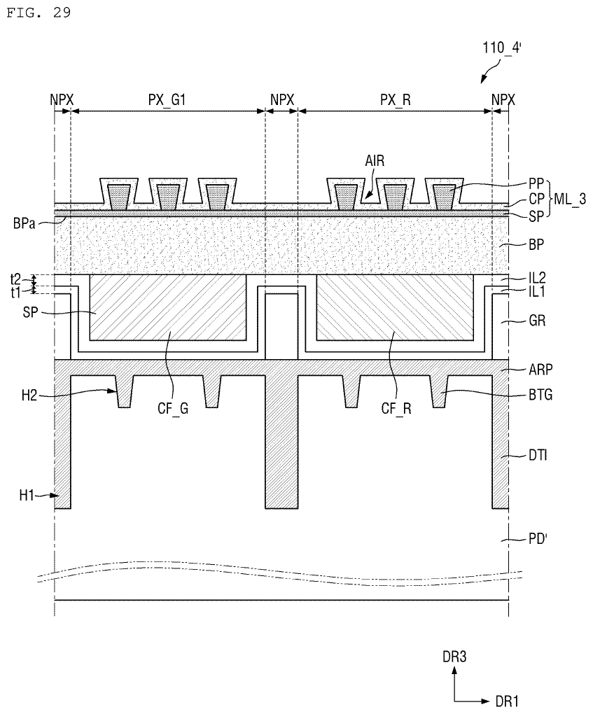

Subsequently, as shown in FIG. 29, a capping unit CP is formed. The capping unit CP may be arranged on the top surface of the support unit SP and the side and top surfaces of the post units PP, respectively. The capping unit CP may include the same material as the base unit BP. For example, the capping unit CP may include a low temperature oxide (LTO) film. The low temperature oxide (LTO) film may be formed at a low temperature lower than 200° C. For example, although the low temperature oxide film may include silicon oxide SiO₂, the embodiments of the present specification are not limited thereto. For example, although the capping unit CP may include silicon oxide nitride SiON or hafnium oxide HfO₂, the embodiments of the present specification are not limited thereto.

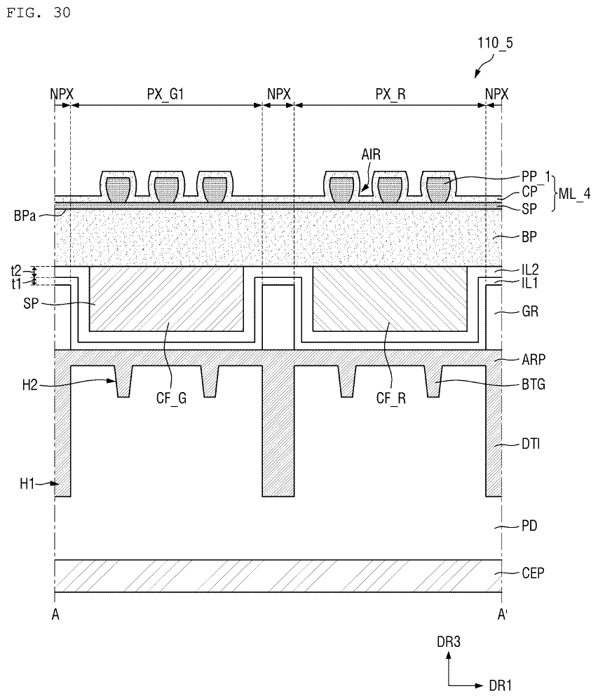

FIG. 30 is a cross-sectional view showing a pixel array based on another embodiment of the disclosed technology.

Referring to FIG. 30, the side surface of the post unit PP_1 of the meta-lens layer ML_4 of the pixel array 110_5 according to this embodiment may have a curved shape.

Describing in more detail, the side surface of the post unit PP_1 according to this embodiment may be formed based on the process of forming the carbon layer CBL′ and the third insulating layer IL3′ of FIG. 25. For example, the carbon layer CBL′ may be excessively etched in the process of etching the carbon layer CBL′ through the third photoresist PR3. Accordingly, as the post layer PP′ fills the gaps between the excessively etched carbon layer CBL′ in the process of forming the post layer PP′ of FIG. 26, the side surface of the post unit PP_1 may have a curved shape.

Even in this embodiment, as the plurality of post units PP_1 is directly arranged on the support unit SP, they may not be broken although air AIR is arranged between adjacent post units PP_1.

In addition, as the capping unit CP is directly arranged on the top surface of the support unit SP and the side and top surfaces of the post units PP_1, the plurality of post units PP_1 may be prevented from being broken as the physical impact applied to the plurality of post units PP_1 is alleviated. In addition, as shown in FIG. 8, as the first photoresist PR1 covers and protects the post units PP_1, the physical impact applied to the plurality of post units PP_1 is alleviated and thus the plurality of post units PP_1 may be prevented from being broken.

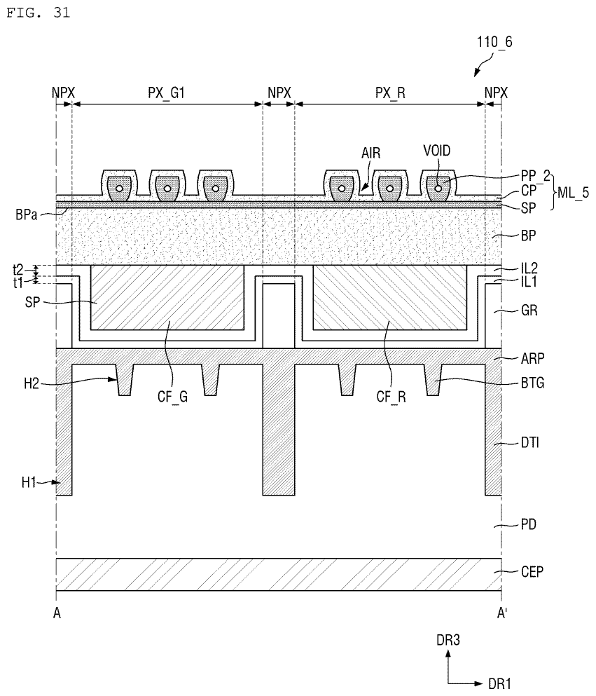

FIG. 31 is a cross-sectional view showing a pixel array based on another embodiment of the disclosed technology.

Referring to FIG. 31, the pixel array 110_6 according to this embodiment is different from the pixel array 110_5 according to FIG. 30 in that the post unit PP_2 of the meta-lens layer ML_5 includes a void VOID therein.

In this implementation, the post unit PP_2 according to this embodiment may include a void VOID therein. The void VOID may be formed based on the process of forming the carbon layer CBL′ and the third insulating layer IL3′ of FIG. 25. For example, the carbon layer CBL′ may be excessively etched in the process of etching the carbon layer CBL′ through the third photoresist PR3. Accordingly, as the post layer PP′ fills the gaps between the excessively etched carbon layer CBL′ in the process of forming the post layer PP′ of FIG. 26, the side surface of the post unit PP_1 may have a curved shape. In addition, as the post layer PP′ fills the gaps between the excessively etched carbon layer CBL′, the area filled by the post layer PP′ becomes larger, and the void is highly probable to be generated inside the post layer PP′.

Even in this embodiment, as the plurality of post units PP_2 is directly arranged on the support unit SP, they may not be broken although air AIR is arranged between adjacent post units PP_2.

In addition, as the capping unit CP is directly arranged on the top surface of the support unit SP and the side and top surfaces of the post units PP_2, the plurality of post units PP_2 may be prevented from being broken as the physical impact applied to the plurality of post units PP_2 is alleviated. In addition, as shown in FIG. 8, as the first photoresist PR1 covers and protects the post units PP_2, the plurality of post units PP_2 may be prevented from being broken as the physical impact applied to the plurality of post units PP_2 is alleviated.

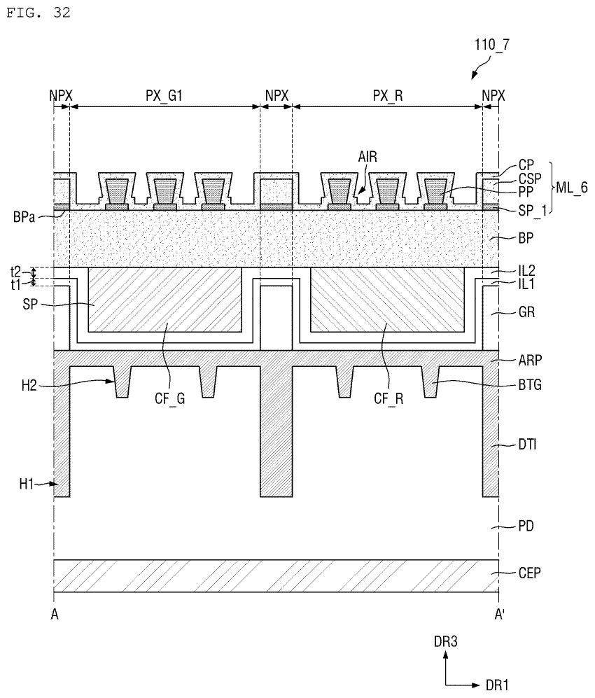

FIG. 32 is a cross-sectional view showing a pixel array according to another embodiment.

Referring to FIG. 32, the pixel array 110_7 according to this embodiment is different from the pixel array 110_4 according to FIG. 23 in that the support unit SP_1 is provided in plural, and the meta-lens layer ML_6 further includes a buffer unit CSP over or on the non-pixel area NPX.

Describing in more detail, the plurality of support units SP_1 may be arranged to be spaced apart from each other. The support unit SP_1 may include, for example, oxide. For example, although the support unit SP_1 may include titanium oxide TiO₂, the embodiments of the present specification are not limited thereto.

A post unit PP may be arranged on the support unit SP_1 on the pixel areas PX_G1 and PX_R, and a buffer unit CSP may be arranged on the support unit SP_1 on the non-pixel area NPX. The post unit PP may include, for example, oxide. For example, although the post unit PP may include titanium oxide TiO₂, the embodiments of the present specification are not limited thereto.

The buffer unit CSP may include the same material as the base unit BP. For example, the buffer unit CSP may include a low temperature oxide (LTO) film. The low temperature oxide (LTO) film may be formed at a low temperature lower than 200° C. For example, although the low temperature oxide film may include silicon oxide SiO₂, the embodiments of the present specification are not limited thereto. For example, although the buffer unit CSP may include silicon oxide nitride SiON or hafnium oxide HfO₂, the embodiments of the present specification are not limited thereto.

The capping unit CP may directly contact the top and side surfaces of the buffer unit CSP, the side surface of the support unit SP_1, the top surface of the base unit BP, the top surface of the support unit SP_1 exposed by the post units PP, and the side and top surfaces of the post units PP.

The capping unit CP may include the same material as the base unit BP. For example, the capping unit CP may include a low temperature oxide (LTO) film. The low temperature oxide (LTO) film may be formed at a low temperature lower than 200° C. For example, although the low temperature oxide film may include silicon oxide SiO₂, the embodiments of the present specification are not limited thereto. For example, although the capping unit CP may include silicon oxide nitride SiON or hafnium oxide HfO₂, the embodiments of the present specification are not limited thereto.

As described above, in the process of peeling off the insulating film (see LF in FIG. 12), the plurality of post units PP may be broken as physical impact is applied. However, according to the pixel array 110_7 according to this embodiment, as the capping unit CP directly contacts the top and side surfaces of the buffer unit CSP, the side surface of the support unit SP_1, the top surface of the base unit BP, the top surface of the support unit SP_1 exposed by the post units PP, and the side and top surfaces of the post units PP, the plurality of post units PP may be prevented from being broken. In addition, as shown in FIG. 8, as the first photoresist PR1 covers and protects the post units PP, the plurality of post units PP may be prevented from being broken as the physical impact applied to the plurality of post units PP is alleviated.

In addition, as the buffer unit CSP is arranged in the non-pixel area NPX, in the arrangement of the insulating film LF in FIG. 9, the grinding process in FIG. 10, and the peeling of the insulating film LF in FIG. 11, the physical impact applied to the post unit PP can be alleviated.

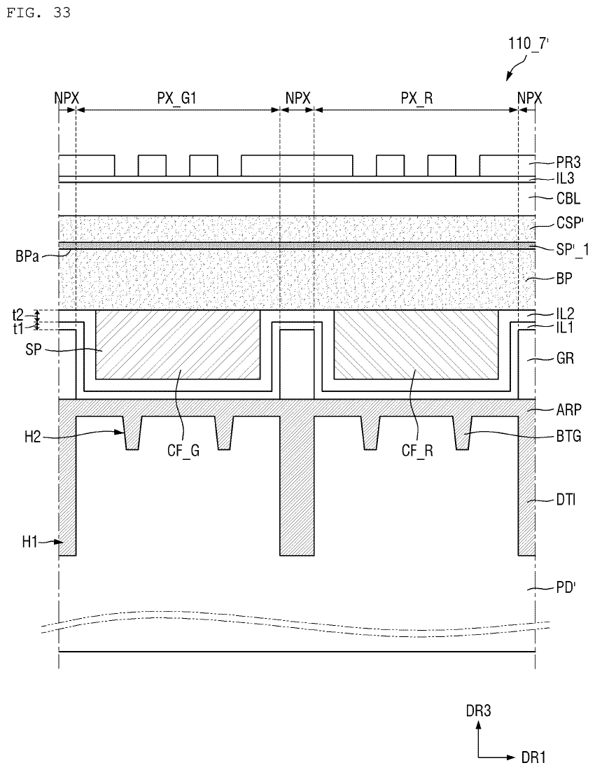

FIGS. 33 to 38 are views of each processing step showing a method of manufacturing a pixel array according to another embodiment of the disclosed technology.

Referring to FIGS. 32 and 33, a support unit SP_1′, a buffer layer SCP′, a carbon layer CBL, and a third insulating layer IL3 are sequentially stacked on the base unit BP of the pixel array 110_6′, and a third photoresist PR3 is formed on the third insulating layer IL3.

The support unit SP_1′ may include, for example, oxide. For example, although the support unit SP_1′ may include titanium oxide TiO₂, the embodiments of the present specification are not limited thereto. Although the carbon layer CBL may include a carbon material, the embodiments of the present specification are not limited thereto. Although the third insulating layer IL3 may include silicon oxide nitride SiON or hafnium oxide HfO2, the embodiments of the present specification are not limited thereto.

The buffer unit CSP′ may include the same material as the base unit BP. For example, the buffer unit CSP′ may include a low temperature oxide (LTO) film. The low temperature oxide (LTO) film may be formed at a low temperature lower than 200° C. For example, although the low temperature oxide film may include silicon oxide SiO₂, the embodiments of the present specification are not limited thereto. For example, although the buffer unit CSP′ may include silicon oxide nitride SiON or hafnium oxide HfO₂, the embodiments of the present specification are not limited thereto.

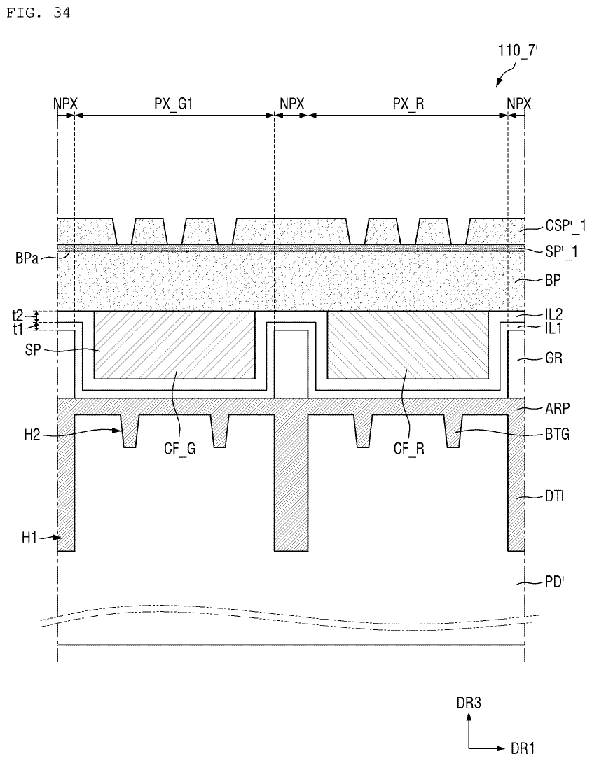

Subsequently, as shown in FIG. 34, a buffer unit CSP′_1 and a third insulating layer IL3′ are formed using the third photoresist PR3 as a mask. The carbon layer (see CBL in FIG. 33) is removed. The buffer unit CSP′_1 may be configured of a plurality of patterns.

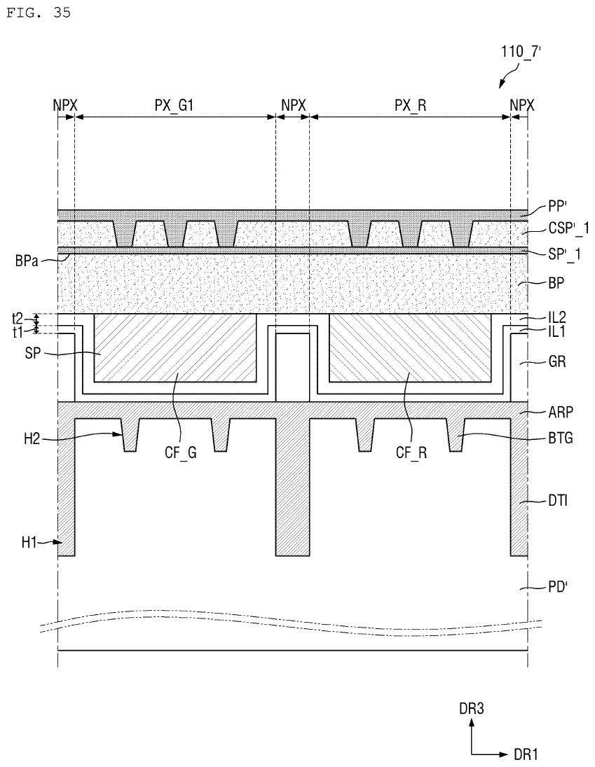

Subsequently, as shown in FIG. 35, a post layer PP′ is formed on the buffer unit CSP′_1 and the third insulating layer IL3′. The post layer PP′ may include, for example, oxide. For example, although the post layer PP′ may include titanium oxide TiO₂, the embodiments of the present specification are not limited thereto.

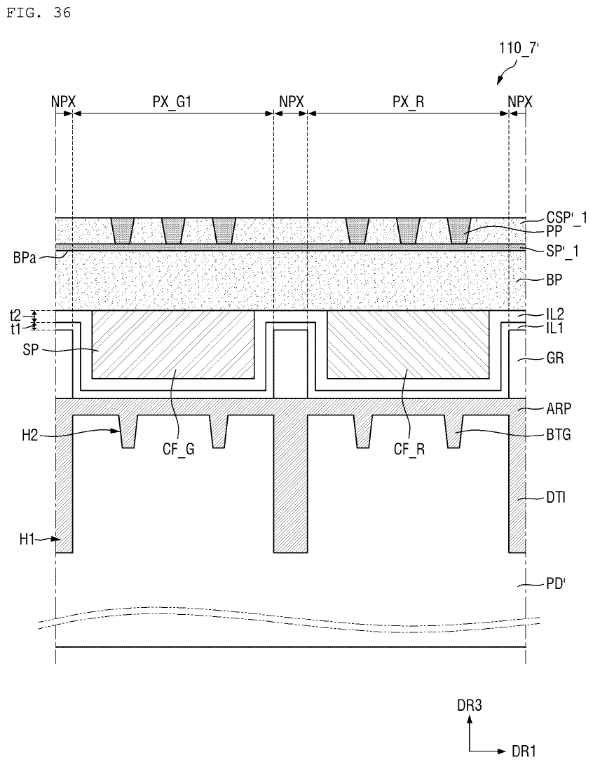

Subsequently, as shown in FIG. 36, the post unit PP is formed by removing the post layer PP′ on the buffer unit CSP′_1. Although the process of removing the post layer PP′ on the buffer unit CSP′_1 may be chemical mechanical polishing (CMP), the embodiments of the present specification are not limited thereto. By removing the post layer PP′ on the buffer unit CSP′_1, the top surface of the buffer unit CSP′_1 and the top surface of the post unit PP may be positioned on the same line.

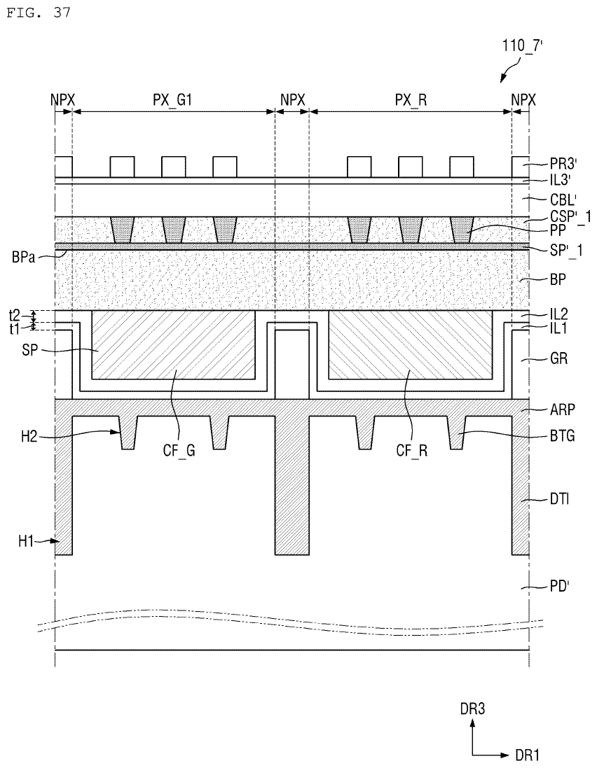

Subsequently, as shown in FIG. 37, a carbon layer CBL′, a third insulating layer IL3′, and a third photoresist PR3′ are sequentially formed on the post unit PP and the buffer unit CSP′_1. The third photoresist PR3′ may overlap the post unit PP and be arranged in the non-pixel area NPX.

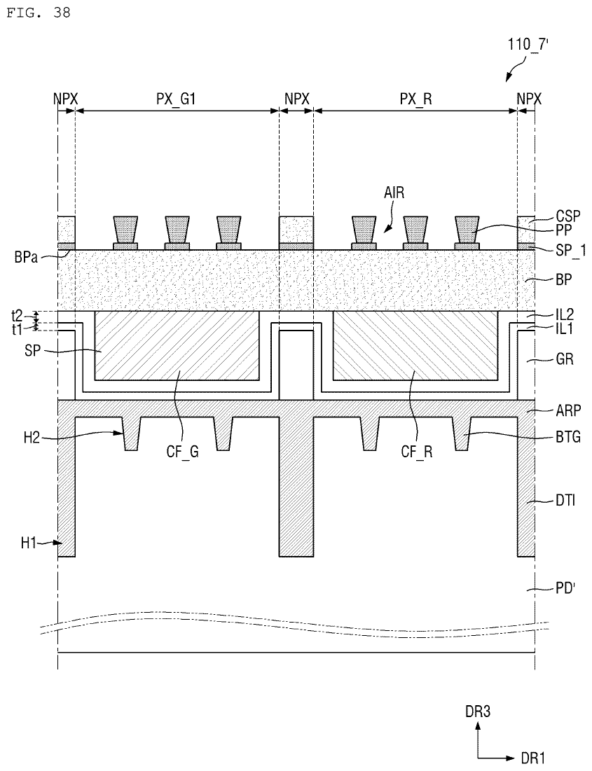

Subsequently, as shown in FIG. 38, a support unit SP_1, a post unit PP, and a buffer unit CSP are formed using the third photoresist PR3′ as a mask. The post unit PP may overlap the support unit SP_1, and the buffer unit CSP may overlap the support unit SP_1. The post unit PP may contact the central portion of the support unit SP_1 and expose a portion of the support unit SP_1.

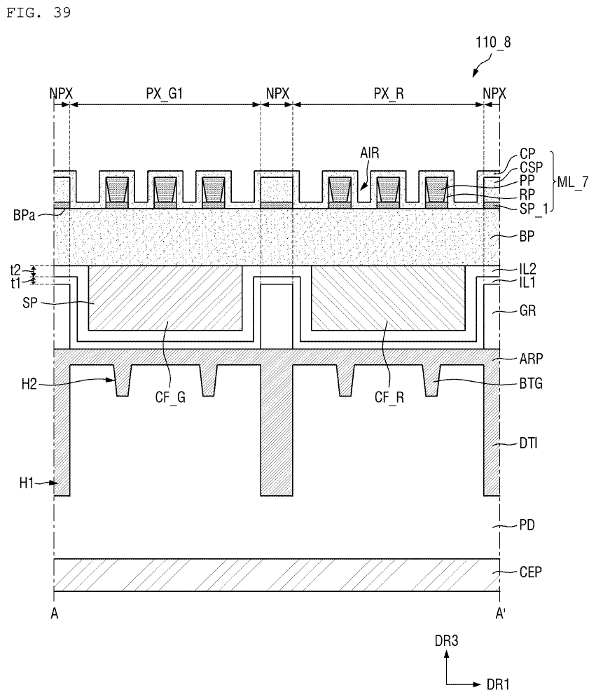

FIG. 39 is a cross-sectional view showing a pixel array according to another embodiment of the disclosed technology.

Referring to FIG. 39, the meta-lens layer ML_7 of the pixel array 110_8 according to this embodiment is different from the pixel array 110_7 according to FIG. 32 in that it further includes a residual unit RP arranged between the side surface of the post unit PP and the capping unit CP.

Describing in more detail, the residual unit RP may include the same material as the base unit BP. For example, the residual unit RP may include a low temperature oxide (LTO) film. The low temperature oxide (LTO) film may be formed at a low temperature lower than 200° C. For example, although the low temperature oxide film may include silicon oxide SiO₂, the embodiments of the present specification are not limited thereto. For example, although the residual unit RP may include silicon oxide nitride SiON or hafnium oxide HfO₂, the embodiments of the present specification are not limited thereto.

The residual unit RP may directly contact the top surface of the support unit SP_1 exposed by the post unit PP.

The residual unit RP may be created in the process of forming the support unit SP_1, the post unit PP, and the buffer unit CSP, using the third photoresist PR3′ described in FIG. 38 as a mask. That is, the residual unit RP may be created as the buffer unit (see CSP′_1 in FIG. 37) around the post unit PP is not completely etched.

Even in this embodiment, in the process of peeling off the insulating film (see LF in FIG. 12), the plurality of post units PP may be broken as physical impact is applied. However, according to the pixel array 110_8 according to this embodiment, as the capping unit CP directly contacts the top and side surfaces of the buffer unit CSP, the side surface of the support unit SP_1, the top surface of the base unit BP, the top surface of the support unit SP_1 exposed by the post units PP, and the side and top surfaces of the post units PP, the plurality of post units PP may be prevented from being broken. In addition, as shown in FIG. 8, as the first photoresist PR1 covers and protects the post units PP, the plurality of post units PP may be prevented from being broken as the physical impact applied to the plurality of post units PP is alleviated.

In addition, as the buffer unit CSP is arranged in the non-pixel area NPX, in the arrangement of the insulating film LF in FIG. 9, the grinding process in FIG. 10, and the peeling of the insulating film LF in FIG. 11, the physical impact applied to the post unit PP can be alleviated.

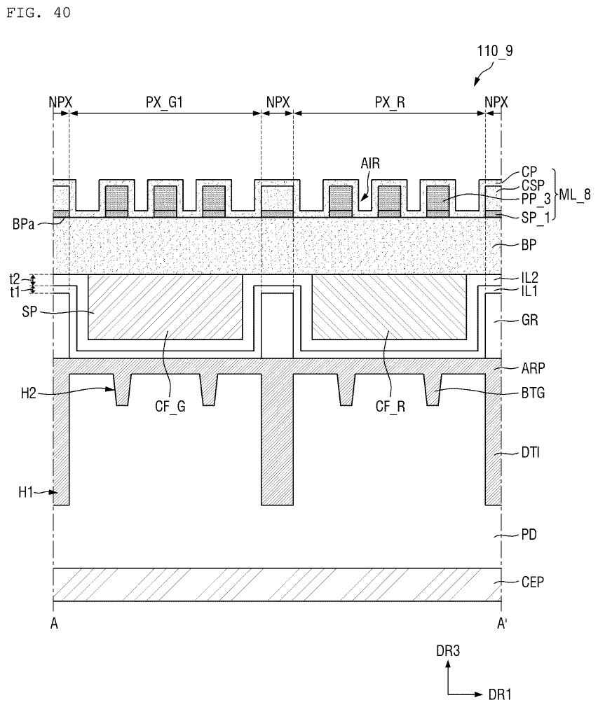

FIG. 40 is a cross-sectional view showing a pixel array according to another embodiment of the disclosed technology.

Referring to FIG. 40, the pixel array 110_9 according to this embodiment is different from the pixel array 110_7 according to FIG. 32 in that the post unit PP_3 of the meta-lens layer ML_8 in contact with the entire top surface of the support unit SP_1.

Even in this embodiment, in the process of peeling off the insulating film (see LF in FIG. 12), the plurality of post units PP_2 may be broken as physical impact is applied. However, according to the pixel array 110_9 according to this embodiment, as the capping unit CP directly contacts the top and side surfaces of the buffer unit CSP, the side surface of the support unit SP_1, the top surface of the base unit BP, the top surface of the support unit SP_1 exposed by the post units PP_2, and the side and top surfaces of the post units PP_2, the plurality of post units PP_2 may be prevented from being broken. In addition, as shown in FIG. 8, as the first photoresist PR1 covers and protects the post units PP_2, the plurality of post units PP_2 may be prevented from being broken as the physical impact applied to the plurality of post units PP_2 is alleviated.

In addition, as the buffer unit CSP is arranged in the non-pixel area NPX, in the arrangement of the insulating film LF in FIG. 9, the grinding process in FIG. 10, and the peeling of the insulating film LF in FIG. 11, the physical impact applied to the post unit PP can be alleviated.

An image sensing device according to various embodiments of the present specification may be described as follows.

An image sensing device according to various embodiments of the present specification comprises: a circuit unit in which a pixel area and a non-pixel area surrounding the pixel area are defined; a photodiode on the circuit unit; a color filter layer on the photodiode; a base unit on the color filter layer; and a meta-lens layer on the base unit, wherein the meta-lens layer includes a support unit on the base unit and a plurality of post units on the support unit, and the plurality of post units is in contact with air.

In the image sensing device according to various embodiments of the present specification, a refractive index of the post unit may be higher than a refractive index of the air, and the refractive index of the post unit may be 1.8 to 2.3.

In the image sensing device according to various embodiments of the present specification, the post unit may include titanium oxide TiO₂.

In the image sensing device according to various embodiments of the present specification, the post unit may be formed to be integrated with the support unit, and may include the same material as the support unit.

In the image sensing device according to various embodiments of the present specification, the base unit may include silicon oxide SiO₂.

In the image sensing device according to various embodiments of the present specification, the pixel area may include a first sub-pixel and a second sub-pixel adjacent to the first sub-pixel, the color filter layer may include a first color filter on the first sub-pixel and a second color filter on the second sub-pixel, and the meta-lens layer on the first sub-pixel may make first light enter the first color filter and make second light enter the second color filter.

An image sensing device according to various embodiments of the present specification comprises: a circuit unit in which a pixel area and a non-pixel area surrounding the pixel area are defined; a photodiode on the circuit unit; a color filter layer on the photodiode; a base unit on the color filter layer; and a meta-lens layer on the base unit, wherein the meta-lens layer includes a plurality of post units on the base unit and a capping unit covering the plurality of post units, and air is arranged between the plurality of post units adjacent to each other.

In the image sensing device according to various embodiments of the present specification, a material of the capping unit may be the same as a material of the base unit.

In the image sensing device according to various embodiments of the present specification, the base unit may include a first base unit that does not overlap the post unit, and a second base unit that overlaps the post unit, and a thickness of the second base unit may be smaller than a thickness of the first base unit.

In the image sensing device according to various embodiments of the present specification, a roughness of a top surface of the second base unit may be greater than a roughness of a top surface of the first base unit.

In the image sensing device according to various embodiments of the present specification, the meta-lens layer may further include a support unit between the base unit and the plurality of post units, and a material of the support unit may be the same as a material of the post unit.

In the image sensing device according to various embodiments of the present specification, a side surface of the post unit may have a curved shape.

In the image sensing device according to various embodiments of the present specification, a void may be formed inside the post unit.

In the image sensing device according to various embodiments of the present specification, the support unit may include a plurality of support patterns spaced apart from each other.

In the image sensing device according to various embodiments of the present specification, the post unit may expose a portion of a top surface of the plurality of support patterns, and the capping unit may be directly in contact with the exposed top surface of the support pattern.

In the image sensing device according to various embodiments of the present specification, the meta-lens layer may further include a residual unit between the capping unit and the post unit, and a material of the residual unit may be the same as a material of the base unit.

In the image sensing device according to various embodiments of the present specification, the post unit may be in contact with an entire top surface of the support unit.

In the image sensing device according to various embodiments of the present specification, the meta-lens layer may further include a buffer unit arranged in the non-pixel area, and the buffer unit may include the same material as the base unit.

A method of manufacturing an image sensing device comprises the steps of: forming a circuit unit in which a pixel area and a non-pixel area surrounding the pixel area are defined, a photodiode layer on the circuit unit, and a color filter layer on the photodiode layer; forming a base unit on the color filter layer; and forming a meta-lens layer, wherein the step of forming a meta-lens layer includes the steps of: forming a base unit on the color filter layer; forming a plurality of post units on the base unit; and forming a capping unit on the plurality of post units, wherein at the step of forming a plurality of post units on the base unit, the plurality of post units is in contact with air.

In the method of manufacturing an image sensing device according to various embodiments of the present specification, a material of the capping unit may be the same as a material of the base unit.

The method of manufacturing an image sensing device according to various embodiments of the present specification may further comprise, after the step of forming a meta-lens layer, the step of arranging a filling layer on the meta-lens layer and an insulating film on the filling layer.

The method of manufacturing an image sensing device according to various embodiments of the present specification may further comprise, after the step of arranging a filling layer on the meta-lens layer and an insulating film on the filling layer, the step of grinding the photodiode layer.

The method of manufacturing an image sensing device according to various embodiments of the present specification may further comprise, between the step of forming a base unit on the color filter layer and the step of forming a plurality of post units on the base unit, the steps of arranging a photoresist on the base unit and forming a post layer on the photoresist.

The method of manufacturing an image sensing device according to various embodiments of the present specification may further comprise, between the step of arranging a photoresist on the base unit and the step of forming a post layer on the photoresist, the steps of forming a recess pattern on a surface of the base unit.

The method of manufacturing an image sensing device according to various embodiments of the present specification may further comprise, between the step of forming a base unit on the color filter layer and the step of forming a post layer on the photoresist, the steps of forming a support unit on the base unit, a carbon layer on the support unit, and an insulating layer on the carbon layer.

The method of manufacturing an image sensing device according to various embodiments of the present specification may further comprise, between the step of forming a base unit on the color filter layer and the step of forming a post layer on the photoresist, the steps of forming a support unit on the base unit, a buffer layer on the support unit, a carbon layer on the buffer layer, and an insulating layer on the carbon layer.

Only a few implementations and examples are described and other implementations, enhancements and variations can be made based on what is described and illustrated in this patent document.

What is claimed is:

1. An image sensing device comprising:
a circuit region including a pixel area and a non-pixel area surrounding the pixel area;
a photodetector located in the pixel area and configured to receive light and produce an electrical signal in response to the light and disposed in the circuit region;
a color filter layer including a portion over the photodetector and configured to allow light having a specific color to pass therethrough;
a base disposed over the color filter layer; and
a lens layer including a portion over the photodetector to direct incident light to the photodetector and disposed over the base and including a support and a plurality of posts disposed over the support, the plurality of posts being arranged in contact with air.

2. The image sensing device according to claim 1, wherein a refractive index of a post of the plurality of posts is higher than a refractive index of the air, and the refractive index of the post is 1.8 to 2.3.

3. The image sensing device according to claim 1, wherein a post of the plurality of posts includes titanium oxide (TiO₂).

4. The image sensing device according to claim 1, wherein a post is integrally provided with the support, and includes a same material as the support.

5. The image sensing device according to claim 1, wherein the base includes silicon oxide (SiO₂).

6. The image sensing device according to claim 1, wherein the pixel area includes a first sub-pixel and a second sub-pixel adjacent to the first sub-pixel, the color filter layer includes a first color filter disposed in the first sub-pixel and a second color filter disposed in the second sub-pixel, and the lens layer disposed in the first sub-pixel is configured to direct first light to entering the first color filter and second light to enter the second color filter.

7. An image sensing device comprising:
a circuit region including a pixel area and a non-pixel area surrounding the pixel area;
a photodetector disposed in the circuit region;
a color filter layer disposed over the photodetector;
a base disposed over the color filter layer; and
a lens layer disposed over the base and including a plurality of posts disposed over the base and a capping region covering the plurality of posts, wherein air is arranged between two adjacent ones of the plurality of posts.

8. The image sensing device according to claim 7, wherein a material of the capping region is same as a material of the base.

9. The image sensing device according to claim 7, wherein the base includes a first base not overlapping a post, and a second base overlapping the post, and a thickness of the second base is smaller than a thickness of the first base.

10. The image sensing device according to claim 9, wherein a roughness of a top surface of the second base is greater than a roughness of a top surface of the first base.

11. The image sensing device according to claim 7, wherein the lens layer further includes a support between the base and the plurality of posts, and a material of the support is same as a material of a post.

12. The image sensing device according to claim 11, wherein a side surface of a post has a curved shape.

13. The image sensing device according to claim 11, wherein a void is provided inside a post of the plurality of posts.

14. The image sensing device according to claim 11, wherein the support includes a plurality of support patterns spaced apart from each other.

15. The image sensing device according to claim 14, wherein the post is configured to expose a portion of a top surface of the plurality of support patterns, and the capping region is directly in contact with the exposed top surface of the plurality of support pattern.

16. The image sensing device according to claim 14, wherein the lens layer further includes a residual region between the capping region and the post, and a material of the residual region is same as a material of the base.

17. The image sensing device according to claim 14, wherein the post is in contact with an entire top surface of the support.

18. The image sensing device according to claim 14, wherein the lens layer further includes a buffer arranged in the non-pixel area, and the buffer includes a same material as the base.

19. A method of manufacturing an image sensing device, the method comprising:
forming a circuit region including a pixel area and a non-pixel area surrounding the pixel area, a photodetector layer in the circuit region, and a color filter layer on the photodetector layer;
forming a base over the color filter layer; forming a plurality of posts over the base, the plurality of posts arranged in contact with air; and
forming a capping region over the plurality of posts, the capping region forming a lens layer together with the plurality of posts and the base.

20. The method according to claim 19, wherein a material of the capping region is same as a material of the base.

21. The method according to claim 19, further comprising, arranging a filling layer on the lens layer and an insulating film on the filling layer.

22. The method according to claim 21, further comprising, after the arranging of the filling layer, grinding the photodetector layer.

23. The method according to claim 19, further comprising, between the forming of the base and the forming of the plurality of posts, disposing a photoresist on the base; and
disposing a post layer on the photoresist.

24. The method according to claim 23, further comprising, between the disposing of the photoresist and the disposing of the post layer, forming a recess pattern on a surface of the base.

25. The method according to claim 23, further comprising, between the forming of the base and the forming of the post layer, forming a support on the base, a carbon layer on the support, and an insulating layer on the carbon layer.

26. The method according to claim 23, further comprising, between the forming of the base and the forming of the post layer, forming a support on the base, a buffer layer on the support, a carbon layer on the buffer layer, and an insulating layer on the carbon layer.
